(19) United States
(12) Patent Application Publication
(10) Pub. No.: US 2024/0039549 A1
(43) Pub. Date: Feb. 1, 2024

(54) SYSTEMS, METHODS, AND APPARATUS FOR SPUR REDUCTION INCLUDING ANALOG FREQUENCY SHIFT

(71) Applicant: PRECISION RECEIVERS INCORPORATED, Cross Junction, VA (US)

(72) Inventors: Paul K.W. Jackson, Cross Junction, VA (US); William O'REILLY, Cross Junction, VA (US)

(73) Assignee: PRECISION RECEIVERS INCORPORATED, Cross Junction, VA (US)

(21) Appl. No.: 18/005,824

(22) PCT Filed: Jul. 17, 2021
(86) PCT No.: PCT/US2021/042119

§ 371 Date: Jan. 17, 2023

Related U.S. Application Data
(60) Provisional application No. 63/053,524, filed on Jul. 17, 2020.

(51) Int. Cl. H03M 1/12; H03M 1/66

(52) U.S. Cl. CPC H03M 1/1245; H03M 1/66

(57) ABSTRACT

Methods, systems, computer-readable media, and apparatuses for spurious information reduction in a data signal are presented. Some configurations include mixing a plurality of analog input signals with different corresponding local oscillator signals to generate a corresponding plurality of converted signals; generating, from each of the plurality of converted signals, a corresponding one of a plurality of sampled signals; frequency shifting at least one signal that is based on at least one of the plurality of sampled signals to obtain, from at least the plurality of sampled signals, a plurality of frequency-aligned signals; and performing a common-mode filtering operation, based on information from the plurality of frequency-aligned signals, to produce a digital output signal.

### CROSS-REFERENCE TO RELATED APPLICATIONS

The present Application for Patent claims priority to U.S. Provisional Pat. Appl. No. 63/053,524, entitled “SYSTEMS, METHODS, AND APPARATUS FOR SPUR REDUCTION INCLUDING ANALOG FREQUENCY SHIFT,” filed Jul. 17, 2020 and assigned to the assignee hereof, and the contents of which are incorporated herein by reference.

### FIELD OF THE DISCLOSURE

Aspects of the disclosure relate to signal processing.

### BRIEF SUMMARY

A method for spurious information reduction in a data signal according to a general configuration comprises receiving at least one instance of an analog data signal that has a signal content in an original frequency band; producing a plurality of analog converted signals, including, for each of the plurality of analog converted signals, frequency translating the signal content of the analog data signal from the original frequency band by a corresponding shift frequency to produce the analog converted signal to have the frequency-translated signal content, the corresponding shift frequency being different than the corresponding shift frequency for each other analog converted signal of the plurality of analog converted signals; based on the plurality of converted signals, generating a corresponding plurality of sampled signals, including, for each of the plurality of digital sampled signals, sampling the frequency-translated signal content of at least a corresponding one of the plurality of analog converted signals to produce the digital sampled signal to have a sampled version of the frequency-translated signal content; aligning information from the sampled versions among the plurality of digital sampled signals, based on the corresponding shift frequencies; and performing a common-mode filtering operation, based on the aligned information, to produce a digital output signal.

A system for spurious information reduction in a data signal according to another general configuration comprises an analog converter configured to receive at least one instance of an analog data signal that has a signal content in an original frequency band and to produce a plurality of analog converted signals, wherein the analog converter is configured to, for each of the plurality of analog converted signals, frequency translate the signal content of the analog data signal from the original frequency band by a corresponding shift frequency to produce the analog converted signal to have the frequency-translated signal content, the corresponding shift frequency being different than the corresponding shift frequency for each other analog converted signal of the plurality of analog converted signals. The system also comprises a digital converter configured to receive the plurality of converted signals and to generate a corresponding plurality of sampled signals, wherein the digital converter is configured to, for each of the plurality of digital sampled signals, sample the frequency-translated signal content of at least a corresponding one of the plurality of analog converted signals to produce the digital sampled signal to have a sampled version of the frequency-translated signal content. The system also comprises processing circuitry to align information from the sampled versions among the plurality of digital sampled signals, based on the corresponding shift frequencies, and perform a common-mode filtering operation, based on the aligned information, to produce a digital output signal.

A method of spurious information reduction in a data signal according to another general configuration includes receiving a plurality of analog input signals, each of the plurality of analog input signals being based on a corresponding one of a plurality of instances of a system input signal; based on the plurality of analog input signals, generating a plurality of converted signals, wherein the generating comprises generating a first of the plurality of converted signals by mixing a first of the plurality of analog input signals with a first local oscillator signal that has a first local oscillator frequency, and generating a second of the plurality of converted signals by mixing a second of the plurality of analog input signals with a second local oscillator signal that has a second local oscillator frequency which is different than the first local oscillator frequency; based on the plurality of converted signals, generating a corresponding plurality of sampled signals; frequency shifting at least one signal that is based on at least one of the plurality of sampled signals to obtain, from at least the plurality of sampled signals, a plurality of frequency-aligned signals, wherein each of the plurality of frequency-aligned signals is based on at least a corresponding one of the plurality of sampled signals; and performing a common-mode filtering operation, based on information from the plurality of frequency-aligned signals, to produce a digital output signal. Computer-readable storage media comprising code which, when executed by at least one processor, causes the at least one processor to perform such a method are also disclosed.

A system for spurious information reduction in a data signal according to another general configuration includes an analog converter configured to receive a plurality of analog input signals, each of the plurality of analog input signals being based on a corresponding one of a plurality of instances of a system input signal. The analog converter is configured to generate a first of the plurality of converted signals by mixing a first of the plurality of analog input signals with a first local oscillator signal that has a first local oscillator frequency, and to generate a second of the plurality of converted signals by mixing a second of the plurality of analog input signals with a second local oscillator signal that has a second local oscillator frequency which is different than the first local oscillator frequency. This system also includes a digital converter configured to receive the plurality of converted signals and to generate a corresponding plurality of sampled signals, and a frequency shifter configured to shift at least one signal that is based on at least one of the plurality of sampled signals to obtain, from at least the plurality of sampled signals, a plurality of frequency-aligned signals, wherein each of the plurality of frequency-aligned signals is based on at least a corresponding one of the plurality of sampled signals. This system also includes a common-mode filter configured to perform a common-mode filtering operation, based on information from the plurality of frequency-aligned signals, to produce a digital output signal.

### BRIEF DESCRIPTION OF THE DRAWINGS

Aspects of the disclosure are illustrated by way of example. In the accompanying figures, like reference numbers indicate similar elements.

FIG. 1A shows a block diagram of a system S100 according to a general configuration.

FIG. 1B shows a block diagram of an implementation S110 of system S100.

FIG. 2A shows a block diagram of an implementation S200 of system S100.

FIG. 2B shows a block diagram of an implementation S210 of system 5200.

FIG. 3A shows a block diagram of an implementation AC20 of analog converter subsystem AC10.

FIG. 3B shows a block diagram of an implementation AC25 of analog converter AC20.

FIG. 4 shows an example of an instance of analog converter AC20.

FIG. 5A shows an example of an instance of analog converter AC20.

FIG. 5B shows an example of an instance of analog converter AC20.

FIG. 6A shows a block diagram of an implementation CV20 of converter CV10.

FIG. 6B shows an instance of converter CV20.

FIG. 6C shows a block diagram of an implementation CV30 of converter CV20.

FIG. 7 shows an example of an instance of converter CV20.

FIG. 8A shows a block diagram of an implementation CV40 of converter CV30.

FIG. 8B shows a block diagram of a double-conversion implementation CV50 of converter CV40.

FIG. 9 shows a block diagram of an implementation AC22 of analog converter AC20.

FIG. 10 shows a block diagram of a configuration that includes analog converter AC22.

FIG. 11 shows a block diagram of an architecture for generating local oscillator signals.

FIG. 12 shows a block diagram of an architecture for generating local oscillator signals.

FIG. 13 shows a block diagram of an implementation DC20 of digital converter subsystem DC10.

FIG. 14 shows a block diagram of an example of a signal generation configuration.

FIG. 15 shows a block diagram of an example of a signal generation configuration

FIG. 16 shows a block diagram of an example of a signal generation configuration.

FIG. 17A shows a block diagram of an implementation CM20 of common-mode filter CM10.

FIG. 17B shows a block diagram of an implementation CM30 of common-mode filter CM10.

FIG. 18A shows a block diagram of an implementation CM40 of common-mode filter CM10.

FIG. 18B shows a block diagram of an implementation CM50 of common-mode filter CM10.

FIG. 19A shows a block diagram of an implementation CM60 of common-mode filter CM10.

FIG. 19B shows a block diagram of an implementation CM70 of common-mode filter CM10.

FIG. 20A shows a block diagram of a system S300 according to another general configuration.

FIG. 20B shows a block diagram of a system S400 according to another general configuration.

FIG. 21 shows a block diagram of analog converter AC30.

FIG. 22 shows an example of frequency-domain locations of frequency-translated versions of a signal content.

FIG. 23 shows a block diagram of analog converter AC40.

FIG. 24A shows a block diagram of analog converter AC50.

FIG. 24B shows an example of a double sideband signal presented to one ADC.

FIG. 25 shows a block diagram of a system S500 according to another general configuration.

### DETAILED DESCRIPTION

In WO 2020/150670 A1, configurations are disclosed in which clocks to two (or more) different analog-to-digital converters (ADCs) are modified to cancel the spurs that are unique to each ADC, which sample the same signal via a signal splitter but sample at different frequencies (different sampling rates). This scheme utilizes the concept that the spurious responses of an ADC are mathematically related to the sample clock (SC).

WO 2020/150670 A1 describes a scheme which exploits the characteristic that spurs generated in the analog-to-digital conversion process are mathematically related to the sample clock. Identical instances of the same analog input frequency (AIF) are sampled at different corresponding clock rates, thereby mathematically generating different error spurs in the different sampling processes. Subsequent processing through a common acceptance algorithm allows the scheme to pass the real (true) signal that was presented to the input (i.e., in the AIF).

As mentioned above, spurs generated in the analog-to-digital conversion process are mathematically related to the sample clock. As described below, the spurs are mathematically related to the input frequency as well. If we change the AIF from one ADC input to another, the spurs on the two different ADCs will be different even if both of the ADCs sample at the same frequency (sampling rate). The spurs will shift in frequency due to the expression (i×SC)±(k×AIF), where i and k are nonzero integers, such as at (2×SC±AIF), (3×SC±2×AIF), and so on.

Potential advantages of shifting the AIF and keeping the same sampling rate may include that lining up samples can become less complicated and phase coherency can be made easier. Also, such an approach presents the possibility of utilizing one ADC to implement the design, which may be very advantageous. The two approaches (i.e., presenting the same signal content at different AIFs for digitization, and digitizing the same signal at different sampling rates) may also be combined in unique ways (e.g., as described below).

Several illustrative configurations will now be described with respect to the accompanying drawings, which form a part hereof While particular configurations, in which one or more aspects of the disclosure may be implemented, are described below, other configurations may be used and various modifications may be made without departing from the scope of the disclosure or the spirit of the appended claims.

Although the particular examples discussed herein relate primarily to radio signal processing, it will be understood that the principles, methods, and apparatuses disclosed relate more generally to electromagnetic-wave signal processing, including optical signal processing, and that uses of these principles in such contexts is specifically contemplated and hereby disclosed. The headings within this application are provided for convenience only and are not to limit the description herein in any way.

System

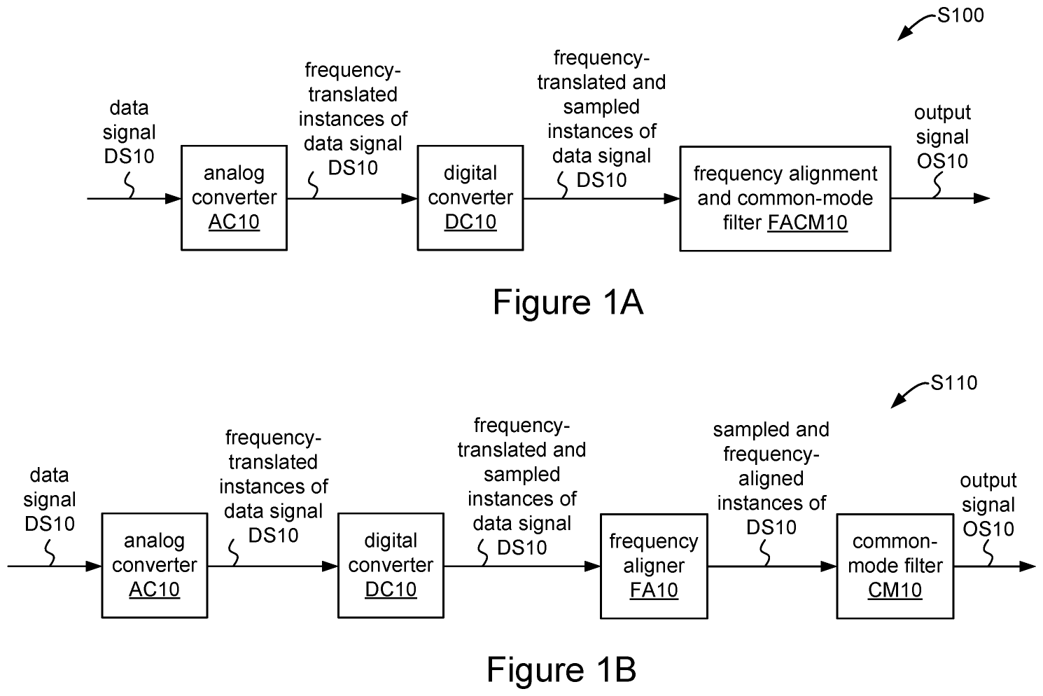

FIG. 1A shows a block diagram of a system S100 according to a general configuration. As illustrated, the spurious information reduction system 5100 includes an analog converter subsystem AC10, a digital converter subsystem DC10, a signal aligner subsystem SA10, and a frequency alignment and common mode filter subsystem FACM10. Analog converter subsystem AC10 is arranged to receive an analog data signal DS10 that has a signal content in an original frequency band and to frequency translate the signal content to two or more different frequency bands to produce two or more respective frequency-translated instances of data signal DS10. Analog converter subsystem AC10 is arranged to receive the frequency-translated instances of data signal DS10 and to produce frequency-translated and digitally sampled instances of data signal DS10. Frequency alignment and common mode filter subsystem FACM10 is arranged to receive the frequency-translated and digitally sampled instances of data signal DS10 and produce an output signal OS10.

FIG. 1B shows a block diagram of an implementation S110 of system S100 in which frequency alignment and common mode filter subsystem FACM10 is implemented to include a frequency aligner FA10 and a common-mode filter CM10. Frequency aligner FA10 is arranged to receive the frequency-translated and digitally sampled instances of data signal DS10 and produce sampled and frequency-aligned instances of data signal DS10, and common-mode filter CM10 is arranged to receive the sampled and frequency-aligned instances of data signal DS10 and produce output signal OS10.

It is assumed herein that the signal content comprises data that is frequency-encoded in the analog data signal DS10, such as in a frequency-modulated (FM) radio-frequency (RF) signal. As such, frequency components of the data signal DS10 typically include frequency components that represent data (e.g., the signal content) and frequency components that represent noise, with the data-related components assumed to be at an appreciably higher magnitude than the noise-related components. The signal content may also be amplitude-modulated and/or phase-modulated on the frequency components that represent data.

In one example, a single device (e.g., a field-programmable gate array (FPGA) or other configurable logic, an application-specific integrated circuit (ASIC), a microprocessor or other central processing unit (CPU) with appropriate program and data memory, a graphics processing unit (GPU) with appropriate program and data memory, etc.) may include frequency alignment and common mode filter subsystem FACM10. In this or other examples, digital converter subsystem DC10, frequency aligner FA10, and common mode filter subsystem CM10 may be implemented on a common substrate or within the same chip.

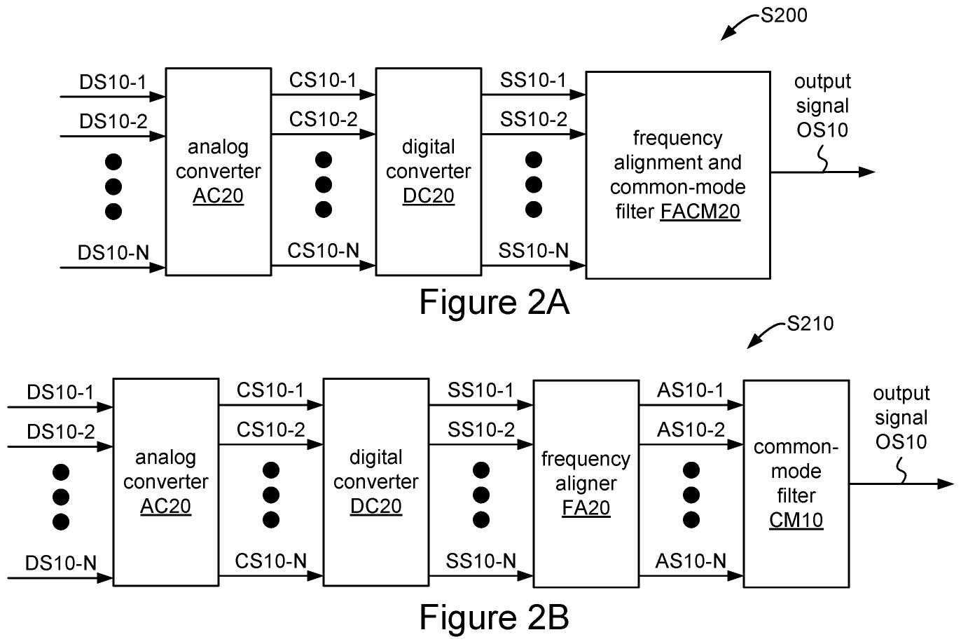

FIG. 2A shows a block diagram of an implementation S200 of system S100. As illustrated, the spurious information reduction system 5200 includes an implementation AC20 of analog converter subsystem AC10, an implementation DC20 of digital converter subsystem DC10, and an implementation FACM20 of frequency alignment and common mode filter subsystem FACM10. FIG. 2B shows a block diagram of an implementation S210 of system S200 in which frequency alignment and common mode filter subsystem FACM10 is implemented to include an implementation FA20 of frequency aligner FA10 and an instance of common-mode filter CM10.

In some cases, a delay or other phase adjustment may be applied to one or more of analog data signals DS10-1, DS10-2, . . . , DS10-N; converted signals CS10-1, CS10-2, . . . , CS10-N, sampled signals SS10-1, SS10-2, . . . , SS10-N, and/or aligned signals AS10-1, AS10-2, . . . , AS10-N to compensate for electrical length differences among devices within system S210 (e.g., mixers, ADCs) and/or the input signal paths to such devices.

Analog Converter

Embodiments of the analog converter subsystem AC20 may include any suitable means for converting instances DS10-1 to DS10-N of an analog input data signal DS10 (where the index number N is an integer having a value of two or greater) into multiple converted signals CS10-1 to CS10-N, such that a distance in frequency in each of the converted signals CS10-1 to CS10-N between a frequency-encoded data profile and a respective frequency-encoded noise profile differs from one of the converted signals CS10-1 to CS10-N to another.

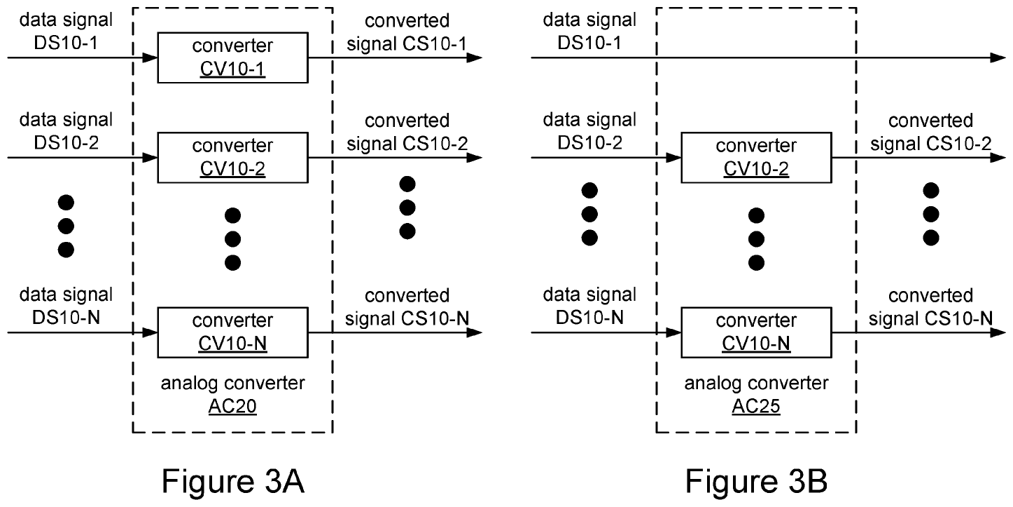

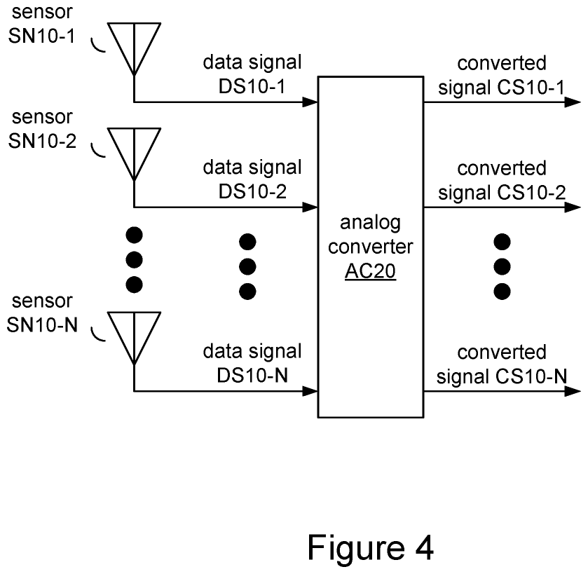

FIG. 3A shows a block diagram of an implementation AC20 of analog converter subsystem AC10. Analog converter subsystem AC20 includes a plurality of instances CV10-1, CV10-2, . . . , CV10-N of a converter CV10, where each instance CV10-1, CV10-2, . . . , CV10-N is configured to receive a corresponding one of instances DS10-1, DS10-2, . . . , DS10-N of an input data signal having signal content in an original frequency band and to frequency translate the signal content to a different respective frequency band. FIG. 4 shows an example in which an instance of analog converter AC20 is arranged to receive each instance DS10-1, DS10-2, . . . , DS10-N of input data signal DS10 from a corresponding one of sensors (e.g., antennas) SN10-1 to SN10-N (possibly via one or more intermediate stages, such as a low-noise amplifier). In one such example, the sensors SN10-1, SN10-2, . . . , SN10-N comprise the antennas of a phased array.

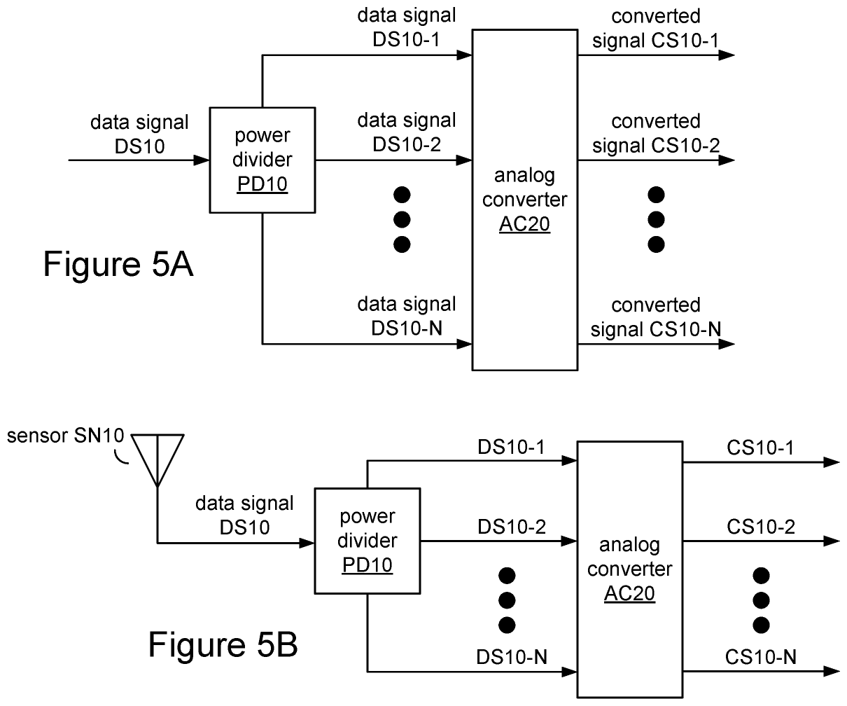

FIG. 5A shows an example in which another instance of analog converter AC20 is arranged to receive each instance DS10-1, DS10-2, . . . , DS10-N of input data signal DS10 from a power divider PD10 (e.g., a power splitter), which may be active or passive and may be implemented according to any appropriate analog signal duplicating technique. An analog data signal DS10 may be received at an input to power divider PD10, and power divider PD10 may effectively make N substantially identical instances of the data signal DS10. FIG. 5B shows a further example in which power divider PD10 may be arranged to receive input data signal DS10 from a sensor (e.g., antenna) SN10 (possibly via one or more intermediate stages, such as a low-noise amplifier).

It is explicitly noted that embodiments of system S200 as described herein may include cases in which analog converter AC20 is implemented to pass-through one of the instances of input signal DS10 (i.e., without frequency translation of the signal content) to digital converter DC20 in place of a corresponding one of converted signals CS10-1 to CS10-N. FIG. 3B shows a block diagram of such an implementation AC25 of analog converter AC20. In such a case, digital converter DC20 may digitally convert the pass-through signal into the corresponding one of sampled signals SS10-1, SS10-2, . . . , SS10-N (e.g., SS10-1) in the same manner as each of the converted signals CS10-2 to CS10-N.

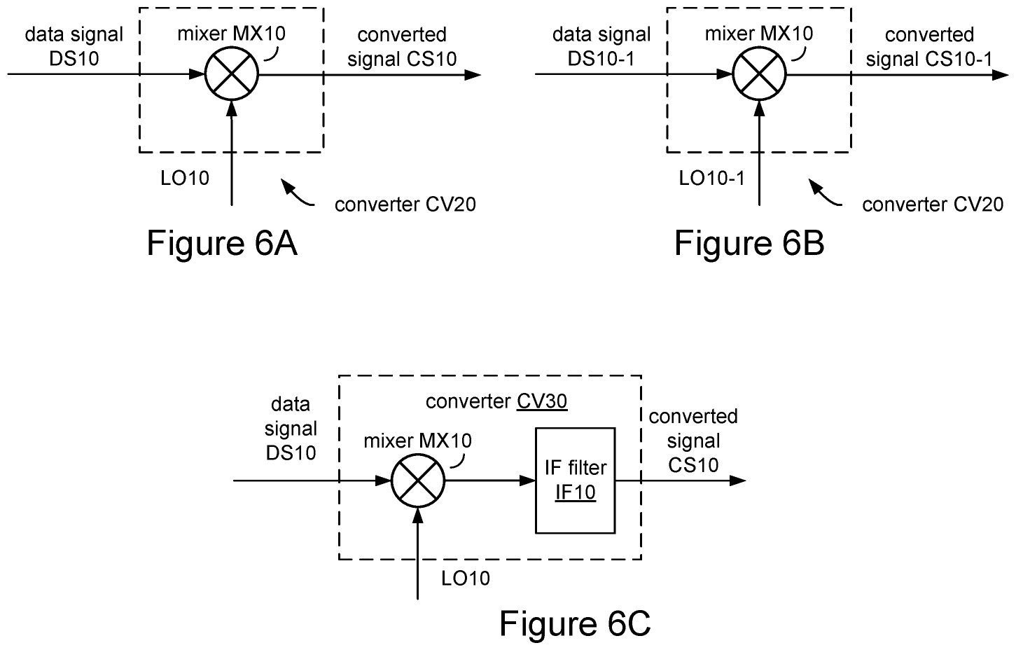

Each of the converters CV10-1, CV10-2, . . . , CV10-N may be implemented to frequency translate the signal content of the analog data signal DS10 from its original frequency band by a corresponding shift frequency, where the corresponding shift frequency may be different for each of the converters CV10-1, CV10-2, . . . , CV10-N (e.g., for all a and b that are integers in the range of from 1 to N, the corresponding shift frequency for converter CV10-a is different than the corresponding shift frequency for CV10-b). FIG. 6A shows a block diagram of an implementation CV20 of converter CV10. Converter CV20 includes a mixer MX10 that is configured to frequency translate the signal content of the analog data signal DS10 from its original frequency band to at least one different frequency band according to the frequency of a local oscillator signal LO10. Mixer MX10 may be implemented to include a nonlinear electrical circuit that creates new frequencies from two signals applied to it (e.g., data signal DS10 and a local oscillator signal LO10). In one example, mixer MX10 is implemented to include a two-input balun (i.e., a three-port device having a matched input and differential outputs) and at least two diodes. In other examples, mixer MX10 is implemented to include a passive mixer (e.g., including two or more diodes and one or more transformers, such as a single-, double-, or triple-balanced mixer), an active mixer (e.g., having at least one transistor and/or FET), a subharmonic mixer, a Gilbert cell mixer, and analog multiplier, a modulator, an optical modulator, a ferromagnetic-core inductor driven into non-linear saturation, and/or any other method of translating frequency content at one analog frequency or band to another analog frequency or band. Each of one or more (possibly all) of the converters CV10-1 to CV10-N of analog converter AC20 may be implemented as a separate instance of converter CV20, and FIG. 6B shows an instance of converter CV20 being arranged as converter CV10-1. It is possible for different ones among the converters CV10-1 to CV10-N of analog converter AC20 to be implemented using respective instances of converter CV20 that have different implementations of mixer MX10.

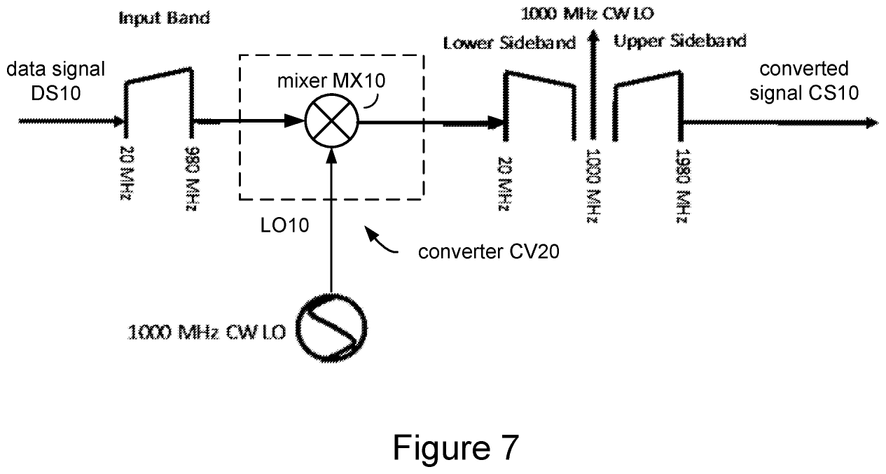

FIG. 7 shows a particular example in which an instance of converter CV20 is arranged to receive an instance of analog data signal DS10 that includes signal content over an original frequency range of 20-980 MHz and an instance of a local oscillator signal LO10 that is a continuous-wave (CW) signal at 1000 MHz. In this example, mixer MX10 mixes these signals to produce the resulting converted signal CS10 as an intermediate frequency (IF) signal having two images about the local oscillator frequency LO10: a first image (“upper sideband”) in which the signal content is frequency-translated to the frequency range of 1020-1980 MHz (e.g., frequency-translated by a corresponding shift frequency of +1000 MHz), and a second image (“lower sideband”) in which the signal content is frequency-translated to the frequency range 980-20 MHz (e.g., frequency-translated by a corresponding shift frequency of −1000 MHz, such that the signal content is reversed in frequency sense). The desired product is typically one or both of these images, but the mixer can also be expected to produce multiple other spurious responses at frequencies of (p×LO)±(q×AIF), where p and q are non-zero integers, LO is the local oscillator frequency, and AIF is the analog input frequency (e.g., RF). In other words, it may be expected that every mathematical combination of the LO and RF may exist in the mixer output, such as LO±2RF, LO±3RF, 2LO±RF, 2LO±2RF, and so on.

FIG. 6C shows a block diagram of an implementation CV30 of converter CV20 that includes an IF filter IF10 (e.g., a channel selection filter). Each of one or more (possibly all) of the converters CV10-1 to CV10-N of analog converter AC20 may be implemented as a separate instance of converter CV30 (e.g., as demonstrated in FIG. 6B with reference to converter CV20). IF filter IF10 may include a bandpass filter configured to pass a desired one of the upper and lower sidebands and to attenuate the other sideband. Such a bandpass filter may also be configured to attenuate the local oscillator signal LO10 in the mixer output and/or the IF filter IF10 may also include a notch filter configured to attenuate the local oscillator signal LO10 in the mixer output.

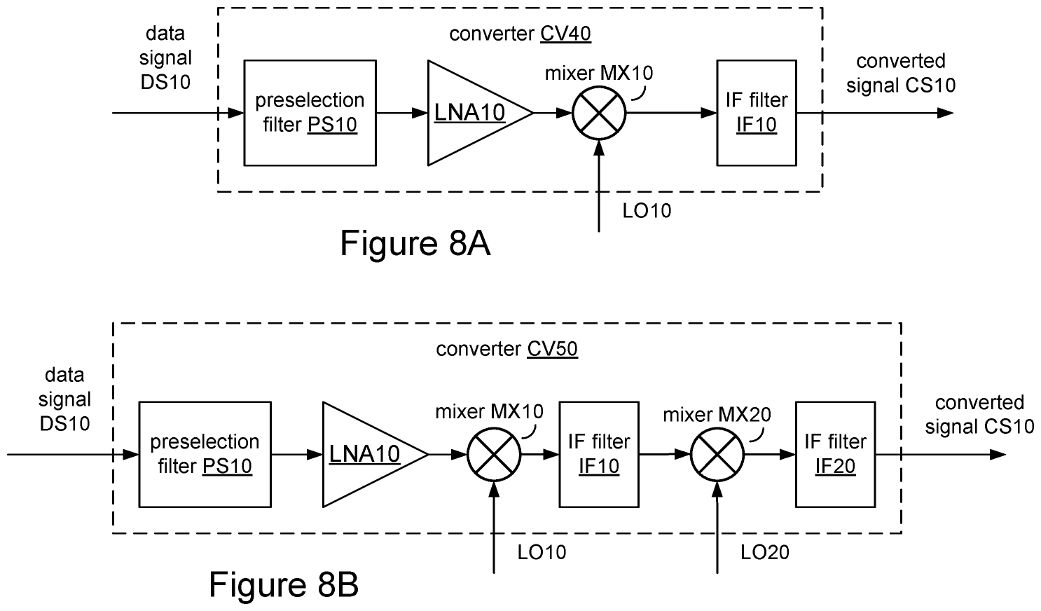

FIG. 8A shows a block diagram of a single-conversion implementation CV40 of converter CV30 that also includes preselection filter PS10, which may include a filter (e.g., a bandpass or lowpass filter) configured to reject an unwanted image in the data signal DS10 that will mix to the same IF range as the signal content. Each of one or more (possibly all) of the converters CV10-1 to CV10-N of analog converter AC20 may be implemented as a separate instance of converter CV40 (e.g., as demonstrated in FIG. 6B with reference to converter CV20). Converter CV40 may optionally include an RF amplifier (e.g., low noise amplifier LNA10) to amplify the selected RF range of data signal DS10 and/or an IF amplifier to amplify the selected IF channel.

FIG. 8B shows a block diagram of a double-conversion implementation CV50 of converter CV40 that includes a second IF stage comprising a second mixer MX20, which is configured to further frequency translate the signal content within the selected IF channel according to the frequency of a second local oscillator signal LO10, and a second IF filter IF20. Mixer MX20 may be implemented to include a nonlinear electrical circuit that creates new frequencies from two signals applied to it (e.g., the IF channel selected by IF filter IF10, and a second local oscillator signal LO20). Mixers MX10 and MX20 may be instances of the same type of mixer (e.g., a passive mixer (e.g., including two or more diodes and one or more transformers, such as a single-, double-, or triple-balanced mixer), an active mixer (e.g., having at least one transistor and/or FET), a subharmonic mixer, a Gilbert cell mixer, and analog multiplier, a modulator, an optical modulator, a ferromagnetic-core inductor driven into non-linear saturation, and/or any other method of translating frequency content at one analog frequency or band to another analog frequency or band), or mixer MX10 may be an instances of a different type of mixer than mixer MX20. IF filter IF20 may include a bandpass filter configured to pass a desired one of the upper or lower sidebands produced by mixer MX20 and to attenuate the other sideband. Such a bandpass filter may also be configured to attenuate the second local oscillator signal LO20 in the mixer output and/or the IF filter IF20 may also include a notch filter configured to attenuate the local oscillator signal LO20 in the mixer output. Converter CV50 may optionally include an IF amplifier to amplify an IF channel as selected by IF filter IF20. Each of one or more (possibly all) of the converters CV10-1 to CV10-N of analog converter AC20 may be implemented as a separate instance of converter CV50 (e.g., as demonstrated in FIG. 6B with reference to converter CV20), and implementations of converter CV50 having additional IF stages (e.g., triple-conversion, quadruple-conversion, etc.) may also be used.

Phased Array

FIG. 4 shows an example in which an instance of analog converter AC20 is arranged to receive each instance DS 10-1, DS10-2, . . . , DS10-N of input data signal DS10 from a corresponding one of sensors (e.g., antennas) SN10-1 to SN10-N (possibly via one or more intermediate stages, such as a low-noise amplifier). In one such example, each of the sensors SN10-1, SN10-2, . . . , SN10-N is an antenna and the sensors SN10-1, SN10-2, . . . , SN10-N comprise the elements of an antenna array, such as a phased array.

In such case, each of the antennas SN10-1, SN10-2, . . . , SN10-N may be coupled to a respective one of N analog front ends (not shown) that receives the antenna feed and produces a corresponding one of instances DS10-1 to DS10-n of data signal DS10. Each of the N analog front ends may include a low-noise amplifier (LNA) and/or one or more filters (e.g., a passband filter) and/or one or more other analog receiver processing components (e.g., one or more mixers, and/or one or more attenuators, and/or one or more switches, and/or one or more oscillators, and/or one or more compressive receivers, etc.). It is also possible to implement each of the N analog front ends to include some or all of the components of the respective one of converters CV10-1, CV10-2, . . . CV10-N (e.g., one or more mixers and/or filters) as such components are described below.

A phased array includes several or many elements, each element being separated from neighboring elements of the array by some factor of a wavelength of the signal (or signals) of interest. In a two-element phased array, for example, the elements are typically separated by half of the wavelength of interest, which corresponds to a phase difference of 180 degrees. Computer processing may be used to support separating elements of a phased array by multiple wavelengths, thereby creating a larger aperture. Phased arrays may come in many forms (e.g., linear arrays, planar arrays, arrays in which the elements are evenly spaced, arrays in which the elements are unevenly (e.g., logarithmically) spaced, etc.) and have proliferated even into the commercial market to the extent that all modern WiFi routers, as well as computers and cell phones, include at least one such array. In one typical form, the elements of a phased array are separated across a flat panel, but such a configuration is not a necessary feature of a phased array. One example of a flat plane phased array can easily be seen in cellular communications towers having three plane triangular base with three-antenna phased arrays. Defense implementations utilize many phased arrays, with the most complicated phased arrays currently having thousands of (e.g., more than 4000) channels.

For a signal that arrives from a direction perpendicular to the face of a planar phased array, each element of the array will receive the signal at approximately the same time. For a signal that arrives from a different direction, each element will receive the signal at a different time, depending on the signal's angle of arrival (AOA) with respect to the array, with typically only minimal differences in the amplitude of the signal as received by different elements. Because the incoming frequency is the same on each of the antenna feeds, the corresponding time shift on each of the respective instances DS10-1 to DS10-N of the data signal DS10 can be thought of as a phase shift. The general formula for angle of arrival (AOA) for two elements spaced a half-wavelength apart is AOA=arctan(ϕ₁−ϕ₂, where ϕ₁ and ϕ₂ indicate the phase angles observed at each element. Accordingly, it may be desired to preserve the phase data within each of the instances DS10-1 to DS10-N of the data signal (e.g., as the respective instances are processed by system S200), as such information may support angle of arrival (AOA) measurements on the incoming signal or beamforming.

Direction finding is one use for phased arrays, and another use is beamforming.. Phased arrays may be used for beamforming, for example, in cellular towers, WiFi routers, and/or radar. Beamforming is a way of enhancing signals that arrive from a certain direction. Enhancement comes from phase-shifting elements to be in phase for signals coming from the direction the operator desires, so that when the received power is combined, signals from the desired direction add fully to the power of the received signals and signals from other directions are not in phase. In this way, power of the desired signal from different elements accumulates and power of other signals from different elements cancels, resulting in an attenuation of those other signals.

Clock Generation And Distribution

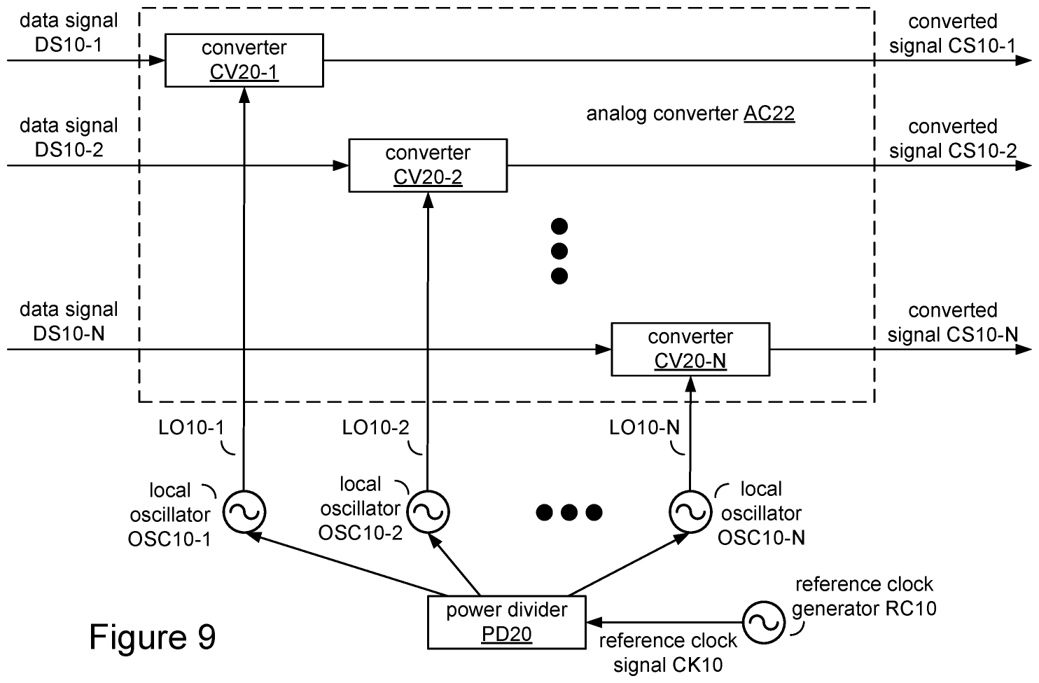

FIG. 9 shows a block diagram of an implementation AC22 of analog converter AC20 in which each of the converters CV10-1, CV10-2, . . . , CV10-N is implemented as a respective instance of converter CV20 (e.g., CV30, CV40, or CV50) that is arranged to receive a corresponding one of instances DS10-1, DS10-2, . . . , DS10-N of data signal DS10 and a corresponding one of local oscillator signals LO10-1, LO10-2, . . . , LO10-N and to produce a corresponding one of converted signals CS10-1, CS10-2, . . . , CS10-N. The frequencies of the local oscillator signals LO10-1, LO10-2, . . . , LO10-N (e.g., the real values of the frequencies of the local oscillator signals LO10-1, LO10-2, . . . , LO10-N) differ from one another.

In some embodiments, each of the respective local oscillator signals LO10-1, LO10-2, . . . , LO10-N may be generated by a corresponding one of N clock generators, which may be free-running and may each be implemented to include, for example, an OCXO (oven-controlled crystal oscillator), a TCXO (temperature-controlled crystal oscillator), another form of crystal oscillator, or another stable oscillator. In other embodiments, the respective local oscillator signals LO10-1, LO10-2, . . . , LO10-N may be derived from the same reference clock signal, such as from a common clock base (e.g., from the same crystal source). It may be desired for local oscillator signals LO10-1, LO10-2, . . . , LO10-N to be mutually phase-coherent. Two clock signals may be considered to be phase-coherent when the phase difference between the two signals at a first point in time is the same (within a tolerance p) as the phase difference between the two signals at a second point in time, when the time interval between the first and second points is equal to the least common multiple of the clock periods of the two signals. The tolerance p may have a value of, for example, 100, 80, 60, 50, 40, 30, 25, 20, ten, eight, six, or five milliradians. In other embodiments, some or all of the respective local oscillator signals LO10-1, LO10-2, . . . , LO10-N may lack mutual phase-coherence.

As shown in the example of FIG. 9, local oscillator signals LO10-1, LO10-2, . . . , LO10-N may be derived by corresponding local oscillators OSC10-1, OSC10-2, . . . , OSC10-N, from a reference clock signal CK10. Reference clock signal CK10 may be generated by a reference clock generator RC10 (also called a “reference oscillator” or “reference source”) and provided to each of the local oscillators OSC10-1, OSC10-2, . . . , OSC10-N via a power divider PD20 (e.g., a power splitter), which may be active or passive and may be implemented according to any appropriate analog signal duplicating technique. Reference clock generator RC10 may be implemented to include, for example, an OCXO, a TCXO, another form of crystal oscillator, or another stable oscillator. In such case, each of the local oscillators OSC10-1, OSC10-2, . . . , OSC10-N may be implemented as, for example, a direct analog synthesizer (also called a mix-filter-divide architecture); a direct digital synthesizer (DDS); or an indirect digital synthesizer (e.g., including a phase-locked-loop or PLL), such as an integer-N synthesizer, a fractional-N synthesizer, a digiphase synthesizer, etc.

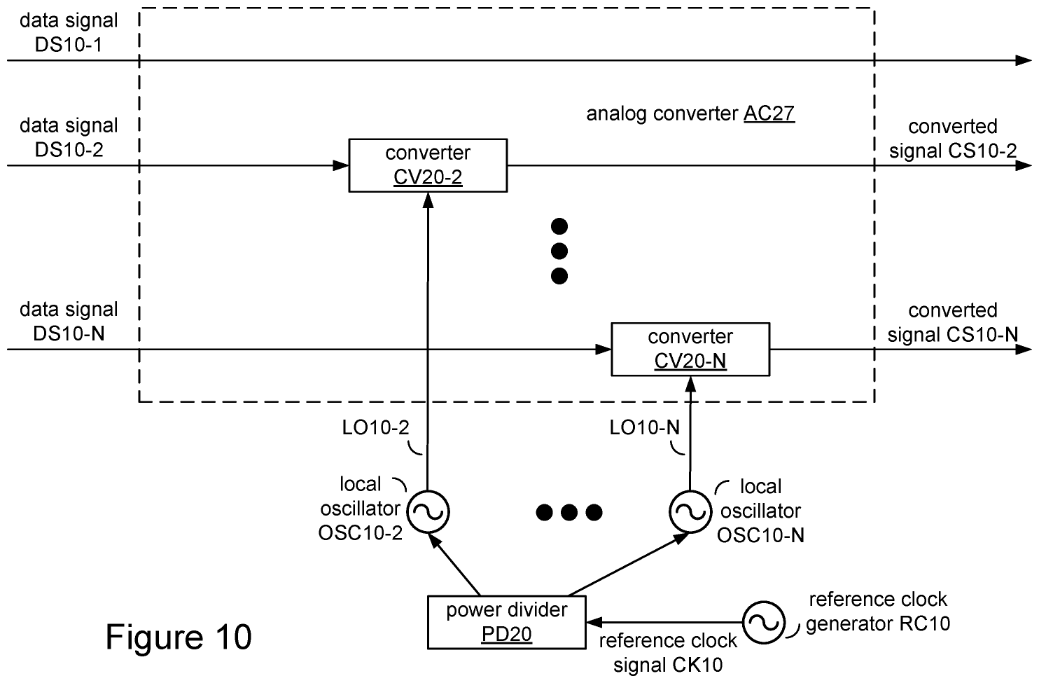

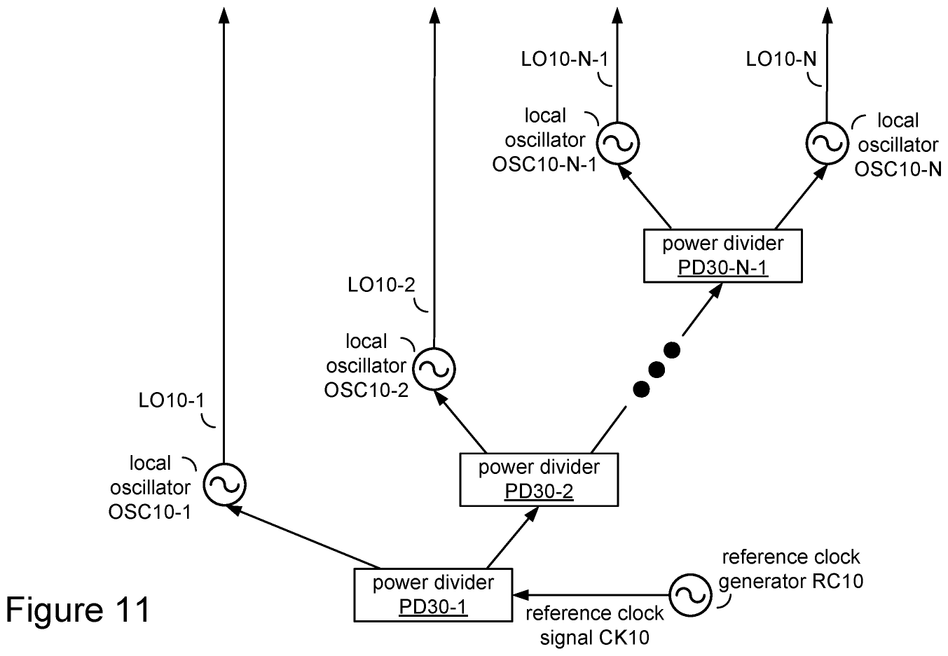

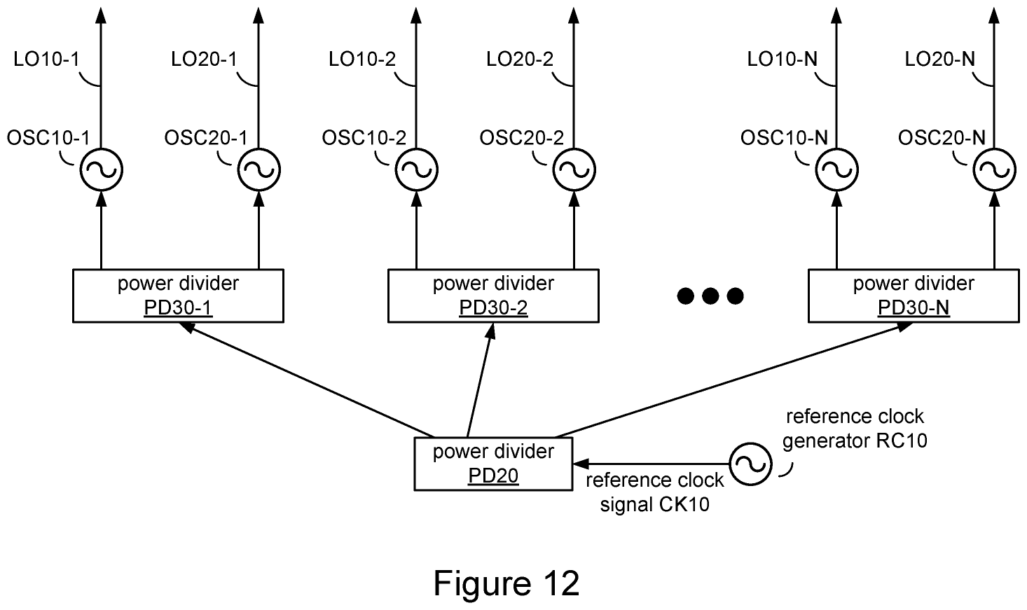

FIG. 10 shows a block diagram of the configuration as shown in FIG. 9 in which analog converter AC25 is replaced by an analogous implementation AC27 of analog converter AC22. FIG. 11 shows a block diagram of an architecture for generating local oscillator signals LO10-1, LO10-2, . . . , LO10-N that includes cascaded instances PD30-1, PD30-2, . . . , PD30-N-1 of a two-output implementation of power divider PD20 (e.g., a power splitter), which may be active or passive and may be implemented according to any appropriate analog signal duplicating technique. FIG. 12 shows a block diagram of an architecture for generating local oscillator signals LO10-1, LO10-2, . . . , LO10-N and LO20-1, LO20-2, . . . , LO20-N (e.g., for driving double-conversion implementations of converters CV10-1, CV10-2, . . . , CV10-N) that includes an instance of power divider PD20 (e.g., a power splitter), which may be active or passive and may be implemented according to any appropriate analog signal duplicating technique, and instances PD30-1, PD30-2, . . . , PD30-N of a two-output implementation of power divider PD20 (e.g., a power splitter), which may be active or passive and may be implemented according to any appropriate analog signal duplicating technique.

Reference clock generator RC10 may be located near and/or integrated into analog converter AC22 (e.g., on the same chip, substrate, or module as analog converter AC22), or may be at another location in the system. Similarly, local oscillators OSC10-1, OSC10-2, . . . , OSC10-N may be located near and/or integrated into analog converter AC22 (e.g., on the same chip, substrate, or module as analog converter AC22) and/or may be located near and/or integrated into the corresponding one of converters CV20-1, CV20-2, . . . , CV20-N (e.g., on the same chip, substrate, or module as the corresponding converter), or may be at another location in the system (e.g., at a same other location as reference clock generator RC10).

Selection of Corresponding Shift Frequencies

The frequency shifts among the frequency-translated signal contents in each of the converted signals CS10-1, CS10-2, CS10-N may be determined from differences among the corresponding shift frequencies. In the example of analog converter AC22 (e.g., arranged as shown in FIG. 9), the frequency-translated signal content in converted signal CS10-2 is shifted relative to the frequency-translated signal content in converted signal CS10-1 by a frequency of +(fLO10-2−fLO10-1); the frequency-translated signal content in converted signal CS10-N is shifted relative to the frequency-translated signal content in converted signal CS10-1 by a frequency of +(fLO10-N−fLO10-1), and the frequency-translated signal content in converted signal CS10-N is shifted relative to the frequency-translated signal content in converted signal CS10-2 by a frequency of (fLO10-N−fLO10-2), where fLO10-1, fLO10-2, and fLO10-N denote the frequencies of local oscillator signals LO10-1, LO10-2, and LO10-N, respectively.

It may be desired for the relative frequency shifts of the frequency-translated signal content among the converted signals CS10-1, CS10-2, . . . , CS10-N to differ from one another. In one example, the relative frequency shift between the frequency-translated signal contents in one pair of the converted signals CS10-1, CS10-2, . . . , , CS10-N has the same magnitude but a different direction than the relative frequency shift between the frequency-translated signal contents in a different pair of the converted signals CS10-1, CS10-2, . . . , CS10-N, but in general it may be desired for the various relative frequency shifts to be mathematically distinct from one another. For example, it may be desired that the relative frequency shift between the frequency-translated signal contents in one pair of the converted signals CS10-1, CS10-2, . . . , CS10-N is not an integer multiple of the relative frequency shift between the frequency-translated signal contents in any other pair of the converted signals CS10-1, CS10-2, . . . , CS10-N. In another example, it may be desired that the relative frequency shifts between the frequency-translated signal contents in any (e.g., all) two pairs among the converted signals CS10-1, CS10-2, . . . , CS10-N are coprime to one another. Such mathematical distinction may provide the advantage that the spur webs of the various channels are less likely to coincide after a frequency alignment performed by subsystem FACM10 or frequency aligner FA10.

FIG. 8B as described above shows an implementation CV50 of converter CV10 (e.g., an upconverter or a downconverter) using two heterodyning stages, and each of converters CV10-1, CV10-2, . . . , CV10-N may be implemented to include a single, double, triple or any other number of stages to accomplish the task of converting the signal content of data signal DS10 to a frequency band accepted by digital converter DC20 (e.g., by a corresponding one of ADCs ADC1-ADCN). In a multi-stage case, it is possible for one or more of the mixing stages to have the same local oscillator frequency in all channels (e.g., fLO10-1=fLO10-2= . . . =fLO10-N, or fLO20-1=fLO20-2= . . . =fLO20-N). In order to cancel analog spurs from both (or all) mixing stages, however, it may be desired instead that, for each of the mixing stages, a different local oscillator frequency is used for that mixing stage in each of the channels. For a case in which each of the converters CV10-1, CV10-2, . . . , CV10-N of analog AC20 is implemented as a respective instance of converter CV50, for example, it may be desired that, for all a and b integers in the range of from 1 to N, fLO10-a≠fLO10-b and fLO20-a≠fLO20-b. As described above, it may be desired to select the offsets among the local oscillator signals such that, at each mixing stage and for each combination of the mixing stages, the relative frequency shift between the frequency-translated signal contents of any pair of channels is not a multiple of the relative frequency shift between the frequency-translated signal contents of any other pair of channels (e.g., such that the relative frequency shift between the frequency-translated signal contents of any pair of converted signals CS10-1, CS10-2, . . . , CS10-N is not a multiple of the relative frequency shift between the frequency-translated signal contents of any other pair of converted signals CS10-1, CS10-2, . . . , CS10-N). As described above, it may be desired to select the offsets among the local oscillator signals such that, at each mixing stage and for each combination of the mixing stages, the relative frequency shifts between the frequency-translated signal contents of any two pairs among the channels are coprime to one another (e.g., such that the relative frequency shifts between frequency-translated signal contents of any two pairs of converted signals CS10-1, CS10-2, . . . , CS10-N are coprime to one another).

When using a double or triple (or higher) conversion radio to implement each of two or more of converters CV10-1, CV10-2, . . . , CV10-N, it may be advantageous to shift the local oscillator frequency from one channel to another on all of the stages, so that all of the stages in the radio will most likely have different frequency spurs from the reference channel. If the local oscillator frequency is unique among the channels only for one of the stages, then potentially only that stage's spurs would be different, and it is possible that only spurs of the modified frequency stage would be cancelled.

An implementation of converter CV10 as described herein may be configured to perform a frequency translation of an analog input signal from one band to another by a fixed amount (e.g., according to a local oscillator signal having a fixed frequency). For example, an implementation of converter CV10 as described herein may be configured to perform block conversion. Alternatively, implementation of converter CV10 as described herein may be configured to perform a frequency translation that is tunable (e.g., according to a local oscillator signal having a tunable frequency).

Several different versions of frequency converters exist. A tuner may be implemented to do contiguous tuning across an input frequency range, and tuning steps of one Hertz are not uncommon. A downconverter may be implemented to tune large bandwidths in large step sizes, sometimes steps which are as large as the bandwidth. A block converter may be configured to not be tunable (e.g., to just convert one block of spectrum to another) and may be used to block-convert a band of interest for input to a tuner or downconverter. It may be desired to use any such form of conversion to implement each of one or more of converters CV10-1, CV10-2, . . . , CV10-N.

Digital Converter

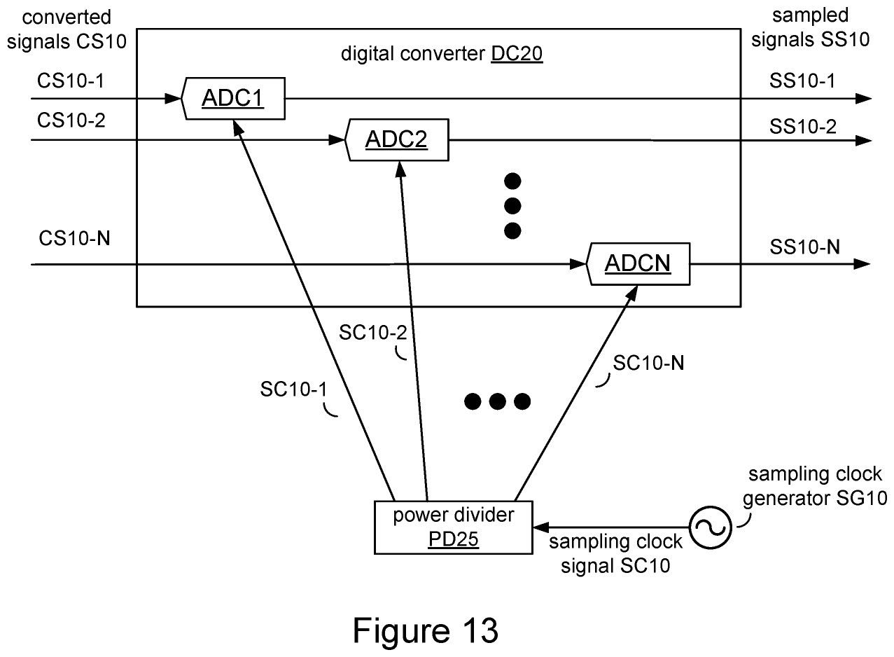

Digital converter subsystem DC20 receives the plurality of converted signals CS10-1, CS10-2, . . . , CS10-N and generates a corresponding plurality of sampled signals SS10-1, SS10-2, . . . SS10-N. FIG. 13 shows a block diagram of an implementation DC20 of digital converter subsystem DC10 that includes a plurality of ADCs ADC1, ADC2, . . . , ADCN, each configured to sample a corresponding one of converted signals CS10-1, CS10-2, . . . , CS10-N according to a sampling clock signal SC10 to generate a corresponding one of sampled signals SS10-1, SS10-2, . . . SS10-N. Each of ADCs ADC1, ADC2, . . . , ADCN may be implemented using a common architecture type (for example, as a flash, successive-approximation (SAR), sigma-delta, pipelined, commutated, interleaved, folding, counting, and/or integrating ADC). Alternatively, one or more of the ADCs ADC1, ADC2, . . . , ADCN may be implemented using a different architecture type than the other ADCs ADC1, ADC2, . . . , ADCN.

The conversion by each of ADCs ADC1, ADC2, . . . , ADCN involves the ADC sampling its input signal according to a sampling rate to generate the corresponding one of sampled signals SS10-1, SS10-2, . . . SS10-N. The terms “sampling rate,” “sampling frequency,” and “clock frequency” are used interchangeably herein (e.g., referring to the rate at which sampling by the ADC is triggered), and the terms “sample period” and “clock period” are also used interchangeably (e.g., referring to the inverse of the sampling rate). When an ADC performs its analog to digital conversion, it typically introduces spurious information (referred to as “spurs”) as an artifact of the sampling. The spurious information typically manifests at frequencies relating to the sampling frequency, such as at harmonics of the sampling frequency. Thus, each of ADCs ADC1, ADC2, . . . , ADCN generates the corresponding one of sampled signals SS10-1, SS10-2, . . . SS10-N to have frequency components representing data from the corresponding one of converted signals CS10-1, CS10-2, . . . , CS10-N; frequency components representing noise from the corresponding one of converted signals CS10-1, CS10-2, . . . , CS10-N; frequency components representing spurious information introduced by the ADC; and frequency components representing other noise introduced by the ADC. While it can be assumed that the noise-related components are at an appreciably lower magnitude than the data-related components, the spur-related components can, at times, be at magnitudes appreciably higher than the noise-related components (possibly at similar magnitudes to the data-related components or even at much higher magnitudes).

Sampling clock signal SC10 may be generated by a sampling clock generator SG10, which may be free-running. Sampling clock generator SG10 may be implemented, for example, as an OCXO (oven-controlled crystal oscillator), TCXO (temperature-controlled crystal oscillator), another form of crystal oscillator, or another stable oscillator. In another example, sampling clock generator SG10 may be configured to derive the clock signal from a reference clock signal. In such case, sampling clock generator SG10 may be implemented, for example, as a direct analog synthesizer (also called a mix-filter-divide architecture); a direct digital synthesizer (DDS); or an indirect digital synthesizer (e.g., including a phase-locked-loop or PLL), such as an integer-N synthesizer, a fractional-N synthesizer, a digiphase synthesizer, etc.

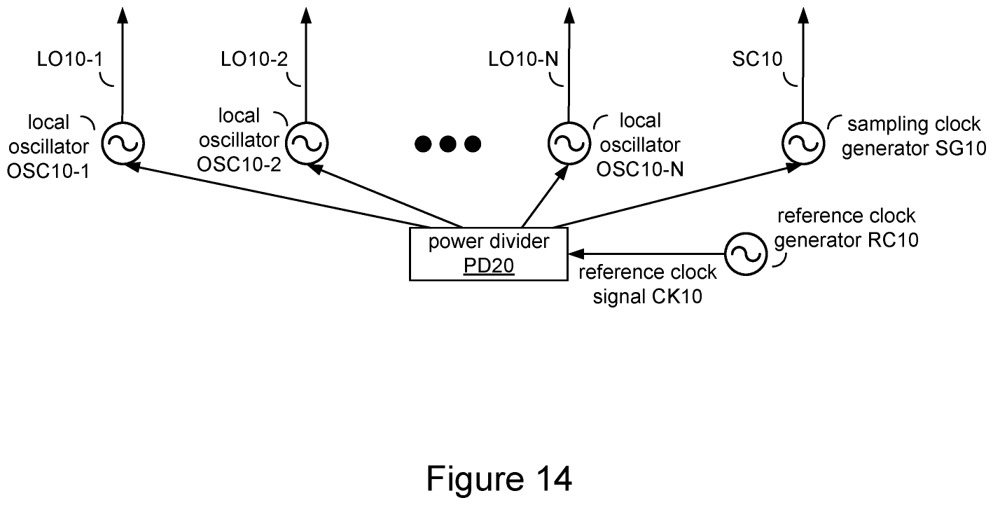

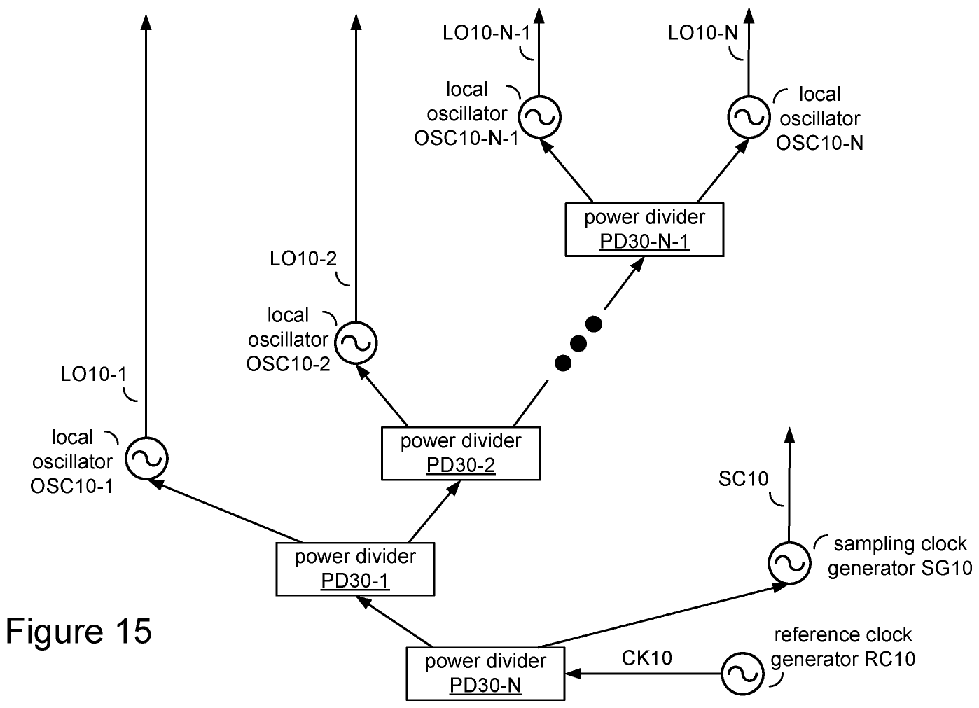

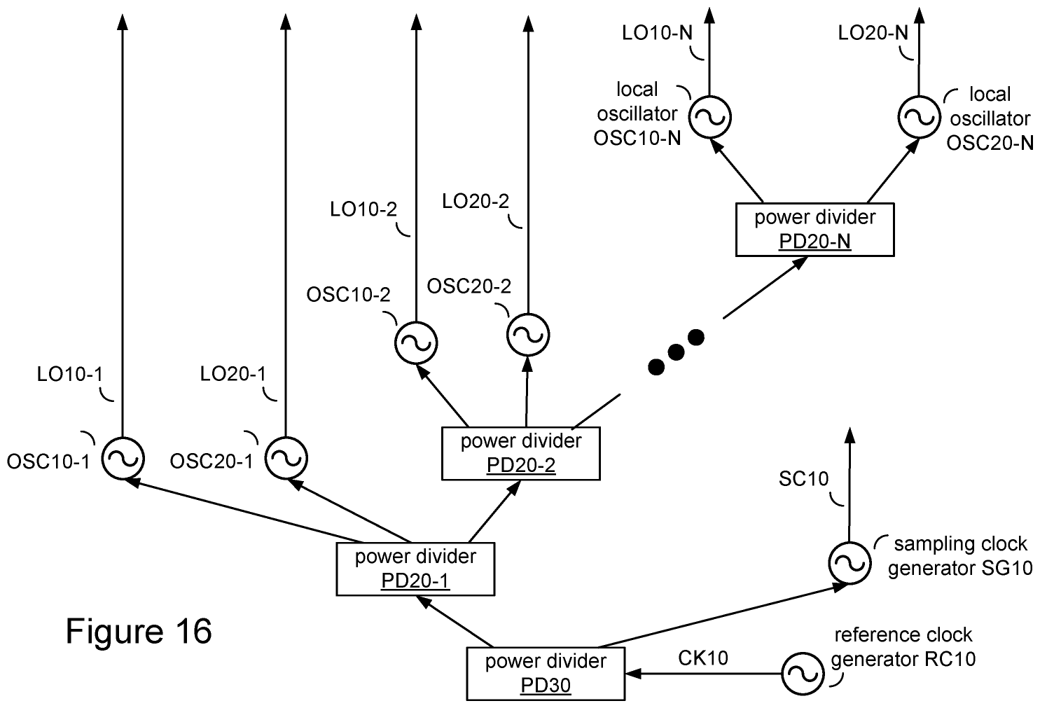

It may be desired for sampling clock signal SC10 and local oscillator signals LO10-1, LO10-2, . . . , LO10-N to be mutually phase-coherent (e.g., to be derived from the same reference clock signal). Two clock signals may be considered to be phase-coherent when the phase difference between the two signals at a first point in time is the same (within a tolerance p) as the phase difference between the two signals at a second point in time, when the time interval between the first and second points is equal to the least common multiple of the clock periods of the two signals. The tolerance p may have a value of, for example, 100, 80, 60, 50, 40, 30, 25, 20, ten, eight, six, or five milliradians. FIGS. 14 and 15 show block diagrams of examples of signal generation configurations as shown in FIGS. 9 and 11, respectively, that also include sampling clock generator SG10. FIG. 16 shows a block diagram of an alternate example of the architecture for generating local oscillator signals LO10-1, LO10-2, . . . , LO10-N and LO20-1, LO20-2, . . . , LO20-N as shown in FIG. 12 that also includes sampling clock generator SG10.

Frequency Aligner

Embodiments of frequency aligner and common-mode filter subsystem FACM10 may include any suitable means for aligning frequency-translated instances of a signal content within multiple respective sampled signals and performing a common-mode filtering operation on aligned values of the signal content to produce an output signal. For example, frequency aligner and common-mode filter subsystem FACM10 may include processing circuitry to align information from the sampled versions among the plurality of digital sampled signals, based on the corresponding shift frequencies, and to perform a common-mode filtering operation, based on the aligned information, to produce a digital output signal. Such processing circuitry may be implemented, for example, to include one or more programmed and/or programmable arrays of logic elements (e.g., logic gates), wherein the programming may be done in hardware, in firmware, and/or in software. Examples of such an array may include an application-specific integrated circuit (ASIC), a field-programmable gate array (FPGA), a digital signal processor (DSP), a microprocessor or other central processing unit (CPU), or a graphics processing unit (GPU).

Frequency aligner and common-mode filter subsystem FACM10 may be implemented to perform operations of frequency alignment and common-mode filtering serially. For example, embodiments of frequency aligner and common-mode filter subsystem FACM10 may include a frequency aligner FA10 and a common-mode filter CM10. Embodiments of frequency aligner FA10 may include any suitable means for aligning frequency-translated instances of a signal content within multiple respective sampled signals to produce frequency-aligned instances of the signal content, and embodiments of common-mode filter CM10 may include any suitable means for performing a common-mode filtering operation on corresponding values of the frequency-aligned instances of the signal content to produce an output signal.

For convenience, the operations of frequency alignment and common-mode filtering are described separately below. It will be understood, however, that subsystem FACM10 may be implemented to perform such operations in parallel (e.g., in an overlapping manner). For example, subsystem FACM10 may be implemented to consume frequency-aligned values of the signal content as they become available such that subsystem FACM10 may be implemented to perform a common-mode filtering operation on frequency-aligned values that correspond to a first frequency component of the signal content before values corresponding to a second frequency component of the signal content have been frequency-aligned. In such case, although the implementation of subsystem FACM10 performs aligning frequency-translated instances of a signal content within multiple respective sampled signals to produce frequency-aligned instances of the signal content, some values of each of the frequency-aligned instances may be consumed (e.g., by a common-mode filtering operation) before other values of the same frequency-aligned instances have been produced (e.g., by a frequency alignment operation).

Embodiments of frequency aligner subsystem FA10 may include any suitable means for converting multiple sampled signals into multiple frequency-aligned signals. For example, frequency aligner FA10 may be configured to shift at least one signal that is based on at least one of the plurality of sampled signals SS10-1, SS10-2, . . . , SS10-N to obtain, from at least the plurality of sampled signals SS10-1, SS10-2, . . . , SS10-N, a plurality of frequency-aligned signals AS10-1, AS10-2, . . . , AS 10-N, wherein each of the plurality of frequency-aligned signals AS10-1, AS10-2, . . . , AS10-N is based on at least a corresponding one of the plurality of sampled signals SS10-1, SS10-2, . . . , SS10-N.

In one example, frequency aligner FA10 is configured to convert each of the sampled signals SS10-1, SS10-2, . . . , SS10-N to a frequency domain (e.g., the FFT domain) and to shift one or more of the signals as converted in order to align the signal content within them in that frequency domain. For a plurality of bins in a frequency domain, for example, frequency aligner FA10 may be configured to calculate, for each each of the sampled signals SS10-1, SS10-2, . . . , SS10-N, a corresponding value for each of the plurality of bins. Frequency aligner FA10 may be configured to perform the shift(s) such that a frequency-encoded data profile (e.g., the signal content) in each of the multiple frequency-aligned signals AS10-1, AS10-2, . . . , AS10-N is aligned in frequency among the frequency-aligned signals AS10-1, AS10-2, . . . , AS10-N, and a respective frequency-encoded noise profile in each of the multiple frequency-aligned signals AS10-1, AS10-2, . . . , AS10-N differs from one of the frequency-aligned signals AS10-1, AS10-2, . . . , AS10-N to another. For example, frequency aligner FA10 may be configured to shift the calculated values for a sampled signal (e.g., SS10-1) among the plurality of bins based on the corresponding shift frequency.

For example, frequency aligner FA10 may be configured to shift one or more of the sampled signals SS10-1, SS10-2, . . . , SS10-N, as converted to the frequency domain, in order to remove offsets among the signal content in each of sampled signals SS10-1, SS10-2, . . . , SS10-N as caused by differences among local oscillator signals LO10-1, LO10-2, . . . , LO10-N. The shifts may be based on the relative frequency shifts of the frequency-translated signal content among the corresponding converted signals CS10-1, CS10-2, . . . , CS10-N as described above. In one such example, one of the channels (e.g., the channel occupied at various stages by signals CS10-1 and SS10-1) is selected as a reference channel, and the sampled signals in the other channels (e.g., SS10-2 to SS10-N) are shifted in the frequency domain according to the frequency shift of the frequency-translated signal content in the channel relative to the frequency-translated signal content in the reference channel. In such a case, the sampled signal SS10-2, as converted to the frequency domain, may be shifted by −(fLO10-2−fLO10-1) to align the frequency-translated signal content in sampled signal SS10-2 with the frequency-translated signal content in sampled signal SS10-1; and the sampled signal SS10-N, as converted to the frequency domain, may similarly be shifted by −(fLO10-N−fLO10-1) to align the frequency-translated signal content in sampled signal SS10-N with the frequency-translated signal content in sampled signal SS10-1.

For a system in which two or more different ADCs sample the same signal content at different sampling rates (e.g., as described in WO 2020/150670 A1), performing common-mode filtering on the resulting sampled signals may be complicated by a difference in bandwidth per sample (whether in a time domain or a frequency domain) among the sampled signals. In such case, it may be desired to normalize the sampled signals to a common bandwidth prior to the common-mode filtering operation. Such a complication may be avoided in a case where the sampling clock is the same for each channel and each channel has been sampled for exactly the same epoch of time. In the absence of binning issues as described below, performing common-mode filtering may be less complicated for an implementation of system 5200 in which all the bins have the same bandwidth and the signal has the same bandwidth.

Binning issues may arise in that, for example, the frequency offsets among the converted signals CS10-1, CS10-2, . . . , CS10-N may not correspond to an integer number of bins. In such a case, similar bins of different sampled signals may represent overlapping but different portions of the relevant frequency domain, even if the bins have the same bandwidth. For a case in which such binning issues may arise (e.g., frequency aligner FA10 is implemented to perform the shift in the FFT domain), such issues may be addressed by, for example, bin splitting, partial binning, and/or interpolation such that, for example, corresponding bins of different sampled signals represent the same portion of the relevant frequency domain. Alternatively, frequency aligner FA10 may be implemented to use another method of spectral analysis such that the frequency shifting may be performed free of binning issues. In such case, frequency aligner FA10 may be implemented to determine frequency content in each of the sampled signals SS10-1. SS10-2, . . . , SS10-N using a method of spectral analysis such as, for example, ARMA, maximum-entropy method of Burg, the Blackman-Tukey method, Capon, EigenVector, MUSIC, methods of autoregressive modeling with moving-average terms (e.g., ARMA, ARIMA), modeling using sine waves or a wavelet (e.g., Daubechies wavelet) transform, etc.

Common Mode Filter

Embodiments of common mode filter subsystem CM10 include those described in WO 2020/150670 A1. Implementations of such a subsystem can omit system-induced noise and pass through to the system output only those signals detected to be present on, for example, the outputs all of the channels (e.g., as aligned). The term “common-mode acceptance” may be used to describe such behavior, as discussed in more detail below.

Embodiments of the common mode filter subsystem CM10 may include any suitable means for producing a digital output signal OS10 by applying common-mode filtering (e.g., including any of the “common mode acceptance” (CMA) approaches described herein) to the frequency-aligned signals AS10-1, AS10-2, . . . , AS10-N. From the frequency responses of two (or more) different channels, common-mode filter CM10 may be used to distinguish what was actually received by the antenna from noise components that were internally generated by the conversion process(es). As such, embodiments of common-mode filter CM10 can perform particular algorithms (such as CMA algorithms) to allow only those frequencies in common to pass through, which can allow the desired bandwidth frequencies to pass unchanged, while blocking the spur frequencies. Embodiments of common-mode filter CM10 can produce a digital output signal OS10 by applying common-mode filtering to the frequency-aligned signals AS10-1, AS10-2, . . . , AS10-N, such that the data-related frequency components are at respective power levels that exceed a floor level, and the spur-related (and other noise-related) frequency components are at respective power levels below the floor level.

As noted above, subsystem FACM10 may be implemented to consume frequency-aligned values of the signal content as they become available such that common-mode filter CM10 may be implemented to perform a common-mode filtering operation on frequency-aligned values that correspond to a first frequency component of the signal content before values corresponding to a second frequency component of the signal content have been frequency-aligned. In such case, although the implementation of subsystem FACM10 performs aligning frequency-translated instances of a signal content within multiple respective sampled signals to produce frequency-aligned instances of the signal content, some values of each of the frequency-aligned instances may be consumed (e.g., by common-mode filter CM10) before other values of the same frequency-aligned instances have been produced (e.g., by frequency aligner FA10, or otherwise by a frequency alignment operation).

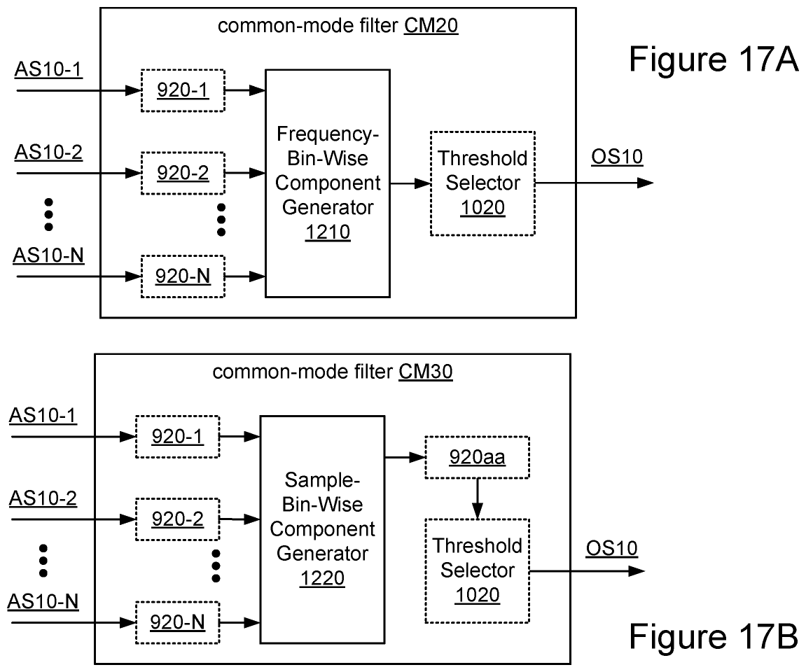

FIGS. 17A, 17B, 18A, 18B, 19A, and 19B show block diagrams of illustrative implementations of common mode filter subsystem CM10, according to various embodiments. Different embodiments of the frequency aligner subsystem FA20 can output the frequency-aligned signals AS10-1, AS10-2, . . . , AS10-N in the time domain or in the frequency domain. Further, various embodiments of the common mode filter subsystem CM10 can operate in the time domain or in the frequency domain. As such, some implementations can be domain-matched, such that time-domain frequency-aligned signals AS10-1, AS10-2, . . . , AS10-N are generated by the frequency aligner subsystem FA20 to be inputs to embodiments of the common mode filter subsystem CM10 that operate in the time domain, and/or frequency-domain frequency-aligned signals AS10-1, AS10-2, . . . , AS10-N are generated by the frequency aligner subsystem FA20 to be inputs to embodiments of the common mode filter subsystem CM10 that operate in the frequency domain.

Other implementations can be domain-unmatched, such that frequency-aligned signals AS10-1, AS10-2, . . . , AS10-N are generated by the frequency aligner subsystem FA20 in a different domain than the operating domain of the common mode filter subsystem CM10. Still other implementations may be partially domain-unmatched, where the outputs of the frequency aligner subsystem FA20 include some frequency-aligned signals AS10-1, AS10-2, . . . , AS10-N generated to be in the time domain and others generated to be in the frequency domain. In any such domain-unmatched, or partially domain-unmatched, implementations, one or more domain transformers 920-1, 920-2, . . . , 920-N can optionally be provided at one or more corresponding inputs of the common mode filter subsystem CM10 to effectively ensure that the received signals match the operating domain of the common mode filter subsystem CM10. Similarly, though not explicitly shown, some embodiments of the common mode filter subsystem CM10 can include a domain transformer 920 at the output of the common mode filter subsystem CM10, such that the digital output signal OS10 is output in a desired domain (e.g., or in both time and frequency domains).

In one example of the class of CMA algorithms, common mode filter subsystem CM10 is implemented to apply a voting algorithm to the frequency-aligned signals AS10-1, AS10-2, . . . , AS10-N in an FFT domain. In one example of a voting algorithm, common mode filter subsystem CM10 is configured to pass only bins that are determined to have signal energy in all of the frequency-aligned signals AS10-1, AS10-2, . . . , AS10-N. In another example of a voting algorithm, common mode filter subsystem CM10 is configured to pass only bins that are determined to have signal energy in a predetermined majority of the frequency-aligned signals AS10-1, AS10-2, . . . , AS10-N. In a further example of a voting algorithm, common mode filter subsystem CM10 is configured to pass the minimum value (e.g., minimum magnitude) among the frequency-aligned signals AS10-1, AS10-2, . . . , AS10-N at each bin. Common mode filter subsystem CM10 may be implemented to apply a voting algorithm (e.g., as in any of the examples described above) to the frequency-aligned signals AS10-1, AS10-2, . . . , AS10-N in a domain of a periodogram-based technique other than FFT as well.

FIGS. 17A and 17B show block diagrams of illustrative implementations of common mode filter subsystem CM10 that use bin-wise component generation in the frequency domain and the time domain, respectively, according to various embodiments. Turning first to FIG. 17A, an implementation CM20 of common mode filter subsystem CM10 is illustrated as including a frequency-bin-wise component generator 1210. Embodiments of the frequency-bin-wise component generator 1210 segregate each of the frequency-aligned signals AS10-1, AS10-2, . . . , AS10-N into a same set of frequency bins. Any suitable number and spacing of frequency bins can be used. For example, frequency bins can be defined in a linear or non-linear manner. At each frequency bin (e.g., of all of the frequency bins, or of a portion of the frequency bins), the frequency-bin-wise component generator 1210 can compute a corresponding output frequency component. The frequency-bin-wise component generator 1210 can then generate its output (e.g., which may be the digital output signal OS10) based on the computed output components.

For example, each of the frequency-aligned signals AS10-1, AS10-2, . . . , AS10-N can have a respective frequency vector at each frequency bin, and each respective frequency vector can have an associated magnitude. In one implementation, at each frequency bin, the frequency-bin-wise component generator 1210 selects the frequency vector having the lowest magnitude for that frequency bin from across the frequency-aligned signals AS10-1, AS10-2, . . . , AS10-N. For example, frequency bins at frequencies corresponding to data will tend to have higher-magnitude frequency vectors in all of the frequency-aligned signals AS10-1, AS10-2, . . . , AS10-N, while frequency bins at frequencies not corresponding to data will tend to have low-magnitude frequency vectors in at least some of the frequency-aligned signals AS10-1, AS10-2, . . . , AS10-N; such an implementation tends to generate an output with reduced vector magnitudes at non-data-related frequencies (i.e., thereby reducing spurious information and other noise).

In some cases, it is possible for more than one of the frequency-aligned signals AS10-1, AS10-2, . . . , AS10-N to include spurious content at the same frequency. In a crowded spectral environment, for example, there is an increased risk that spurious responses from different channels within converter AC20 (e.g., from two or more of converters CV10-1, CV10-2, . . . , CV10-N) could end up on top of each other. In some implementations, frequency-bin-wise component generator 1210 may also be configured to determine whether the magnitude and/or phase of the lowest-magnitude vector is acceptable at each frequency bin (e.g., is within a predetermined window). If the vector's amplitude, phase, or a combination of both (e.g., an IQ value) is not acceptable, such an implementation of generator 1210 selects a substitute value for the frequency bin (e.g., as if neither signal were present at that frequency). In one example, the substitute value is the lowest-magnitude vector in the adjacent lower (and/or adjacent higher) frequency bin.

In another implementation, at each frequency bin, the frequency-bin-wise component generator 1210 selects the frequency vector having the highest magnitude for that frequency bin from across the frequency-aligned signals AS10-1, AS10-2, . . . , AS10-N. Such an implementation can tend to emphasize spurious information and other noise. In another implementation, at each frequency bin, the frequency-bin-wise component generator 1210 computes an average (e.g., mean, median (or other moment), geometric mean, etc.) or other suitable function of the magnitudes of the frequency vectors for that frequency bin from across the frequency-aligned signals AS10-1, AS10-2, . . . , AS10-N. Such an implementation can tend to de-emphasize (reduce the magnitude of) spurious information and other noise.

The output of the frequency-bin-wise component generator 1210 can be used directly as the digital output signal OS10. Additionally or alternatively, the digital output signal OS10 can be generated with added threshold selection after the frequency-bin-wise component generator 1210. For example, as illustrated in FIG. 17A, the output of the frequency-bin-wise component generator 1210 (already a frequency-domain signal) can be processed by a threshold selector 1020, which can discriminate between those frequency components having magnitudes above a threshold level (i.e., the data-related frequency components) and those frequency components having magnitudes below the threshold level (i.e., the non-data-related frequency components). As described above, some embodiments can apply the discriminating to accept the data-related frequency components, and other embodiments can apply the discriminating rejecting the data-related frequency components.

Turning to FIG. 17B, an implementation CM30 of common mode filter subsystem CM10 is illustrated as including a sample-bin-wise component generator 1220. Embodiments of the sample-bin-wise component generator 1220 segregate each of the frequency-aligned signals AS10-1, AS10-2, . . . , AS10-N into a same set of time-domain sample bins. Any suitable number and spacing of time-domain sample bins can be used. For example, time-domain sample bins can be defined in a linear or non-linear manner. At each time-domain sample bins (e.g. of all, or a portion of the time-domain sample bins), the sample-bin-wise component generator 1220 can compute a corresponding output time-domain sample (i.e., as the output component at that time-domain sample bin). Similar to the frequency-domain implementations of FIG. 17A, each of the frequency-aligned signals AS10-1, AS10-2, . . . , AS10-N can have a respective sample vector at each time-domain sample bins, and each respective sample vector can have an associated magnitude. Accordingly, implementations of the sample-bin-wise component generator 1220 can compute the corresponding output time-domain sample for each time-domain sample bin by selecting a minimum sample vector magnitude from across the frequency-aligned signals AS10-1, AS10-2, . . . , AS10-N; by selecting a maximum sample vector magnitude from across the frequency-aligned signals AS10-1, AS10-2, . . . , AS10-N; by computing an average sample vector magnitude from across the frequency-aligned signals AS10-1, AS10-2, . . . , AS10-N; etc.

The sample-bin-wise component generator 1220 can then generate its output based on the computed output components. As discussed with reference to the frequency-domain implementation of FIG. 17A, some embodiments can use the output of the sample-bin-wise component generator 1220 directly as the digital output signal OS10. Additionally or alternatively, the digital output signal OS10 can be generated with added threshold selection after the sample-bin-wise component generator 1220. For example, as illustrated in FIG. 17B, the output of the sample-bin-wise component generator 1220 (a time-domain signal) can be converted to a frequency-domain signal by a domain transformer 920aa and processed by a threshold selector 1020. The threshold selector 1020 can discriminate between those frequency components having magnitudes above a threshold level (i.e., the data-related frequency components) and those frequency components having magnitudes below the threshold level (i.e., the non-data-related frequency components). As described above, some embodiments can apply the discriminating to accept the data-related frequency components, and other embodiments can apply the discriminating rejecting the data-related frequency components.

Common-mode filter CM10 may also be configured to determine whether signals at particular frequency components are true (i.e., present in data signal DS10) or artifacts of the digitizing process. For example, common-mode filter CM10 (e.g., CM20, CM30) may be configured to determine, within output signal OS10 and/or within one or more of frequency-aligned signals AS10-1, AS10-2, . . . , AS10-N, whether a signal at a particular frequency component meets certain parameters, such as whether the signal is within a predetermined window of amplitude, or of phase, or of a combination of amplitude and normalized phase. For application in which system 5200 receives the instances DS10-1, DS10-2, . . . , DS10-N of data signal DS10 from a phased array (e.g., as described above), common-mode filter CM10 may configured to determine a phase value at each bin, which may be used to indicate an angle of arrival (AoA) of the incoming signal at the phased array.

In other examples, the CMA algorithms use different methods of spectral analysis to determine frequency content in each of the ADC outputs. Examples of such methods include the maximum-entropy method of Burg, the Blackman-Tukey method, Capon, EigenVector, MUSIC, and methods of autoregressive modeling with moving-average terms (e.g., ARMA, ARIMA).

The class of CMA algorithms, both parametric and non-parametric, can involve decimating or interpolating one of two input time-series signals (S2) (e.g., SS10-2) so that it matches another input time-series signal (S1) (e.g., SS10-1), although the class also includes algorithms for which such matching is not required. In one embodiment, a cross-correlation analysis or cross-power spectra (e.g., but not limited to, a biased cross-correlation) can be applied, and the output of the cross-correlation becomes a new digital signal. The new digital signal (S1×S2) is a time series that is a hybrid of S1 and S2 from a frequency perspective, represented in the time series. Performing an FFT on S1×S2 yields a new frequency domain data set that does not have the spurs of S1 and S2 represented, but does maintain the signal for S1 and S2 (which should be identical to the digital limits of the system).

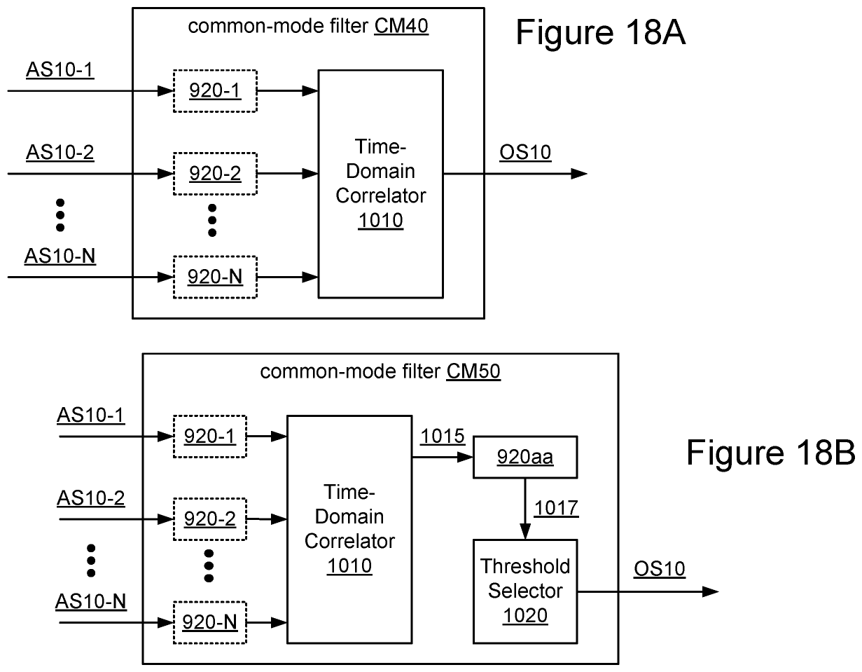

Turning first to FIG. 18A, an implementation CM40 of common mode filter subsystem CM10 is illustrated to include a time-domain correlator 1010. The time-domain correlator 1010 can use any suitable technique to cross-correlate some or all of the frequency-aligned signals AS10-1, AS10-2, . . . , AS10-N in the time domain. Because the frequency-aligned signals AS10-1, AS10-2, . . . , AS10-N encode substantially the same data and substantially different non-data (i.e., spurious information and other noise), the frequency-aligned signals AS10-1, AS10-2, . . . , AS10-N will tend to correlate appreciably more strongly around data-related information than otherwise.

For example, a so-called “cross-power spectrum” computation of two digital input signals (e.g., SS10-1 and SS10-2) can be applied as follows:

S_{ADC1,2}(f)=FFT(ADC1)×FFT⁺(ADC2)/N²

The resultant spectrum is indicated by “S” and is calculated by multiplying the FFT of the first digital input signal “ADC1” (e.g., SS10-1) with the complex conjugate of the FFT of the second digital input signal “ADC2” (e.g., SS10-2), and dividing the result by the square of the FFT length “N.” The asterisk superscript denotes the complex conjugate. Similarly, a so-called “auto power spectrum” computation can be applied as follows, where A is a digital input signal (e.g., ADC1 or ADC2):

$$S ( f ) = \frac{F F T ( A ) \times F F {T}^{*} ( A )}{{N}^{2}}$$

Frequency-based implementations tend to be biased and to involve circular convolution. In some cases, it is desirable to use an approach that is unbiased and involves linear convolution, for example, where there is a wide sense stationary set of data and the variance and mean are known. For the sake of illustration, the above auto power spectrum can be adapted to an auto correlation formula in the time domain for a single vector ( [symbol] ) from the first digital input signal (ADC1) (e.g., SS10-1) as follows:

$${σ}_{xx} ( T ) = \frac{1}{N - 1} {\sum }_{t = 1}^{N} {t - T}_{} {t}_{}$$

where N indicates the length of the vector [symbol] and T indicates an offset in time. The resulting autocorrelation function is a time-series function, and any suitable domain-transforming periodogram (e.g., an FFT or DTFT) may be taken of the autocorrelation function for the frequency domain. For example, according to the Wiener-Khinchin theorem, the power spectral density is the Fourier transform of the autocorrelation. The above computation can be extended (e.g., extending the Wiener-Khinchin theorem to the cross-power spectrum), referring to a vector from the second digital input signal (ADC2) (e.g., SS10-2) as ( [symbol] ), as follows:

$${σ}_{x y} ( T ) = \frac{1}{N - 1} {\sum }_{t = 1}^{N} {t - T}_{} {t}_{}$$

The cross-correlation function for the two digital input signals (e.g., SS10-1 and SS10-2) can thus be derived as follows, where i indicates an offset in time:

$${R}_{x y} ( τ ) = {\sum }_{t = 0}^{T - τ - 1} {t + τ}_{} {t}_{*}^{}$$

Turning back to FIG. 18A, the output of the time-domain correlator 1010 can be the digital output signal OS10. For example, some applications can be coupled with the time-domain output of the time-domain correlator 1010. This digital output signal OS10 represents a digitally converted signal with higher signal-to-noise ratio than would be achieved by directly using any one of the outputs SS10-1, SS10-2, . . . , SS10-N of digital converter DC10.

Other embodiments do not use the output from the time-domain correlator 1010 as the digital output signal OS10, performing further processing instead. For example, FIG. 18B shows another embodiment CM50 of the common mode filter subsystem CM10 that is similar to that of FIG. 18A with added threshold selection. As illustrated, the output of the time-domain correlator 1010 (a time-domain correlated signal 1015) can be converted to frequency domain by a domain transformer 920aa. For example, the domain transformers 920-1, 920-2, . . . , 920-N can apply any domain-transforming periodogram to the time-domain correlated signal 1015 to produce a corresponding frequency-domain correlated signal 1017. The frequency-domain correlated signal 1017 output from the time-domain correlator 1010 may have an appreciable spread in magnitude between data-related frequency components and all other frequency components.

A threshold selector 1020 can process the frequency-domain correlated signal 1017 by discriminating between those frequency components having magnitudes above a threshold level (i.e., the data-related frequency components) and those frequency components having magnitudes below the threshold level (i.e., the non-data-related frequency components). In some embodiments, the discriminating involves accepting those frequency components having magnitudes above the threshold level and rejecting some or all other frequency components, thereby accepting the data-related frequency components and rejecting at least some of the spurious information and other noise. In other embodiments, the discriminating involves rejecting those frequency components having magnitudes above the threshold level and accepting some or all other frequency components, thereby rejecting the data-related frequency components and accepting at least some of the spurious information and other noise. Some implementations of the threshold selector 1020 use a pre-set (e.g., hard-coded) threshold level. Other implementations of the threshold selector 1020 use a programmable (e.g., software-programmable, hardware-selectable, tunable, etc.) threshold level. Other implementations of the threshold selector 1020 use a dynamic threshold level (e.g., that automatically adjusts based on a feedback control loop, or the like).

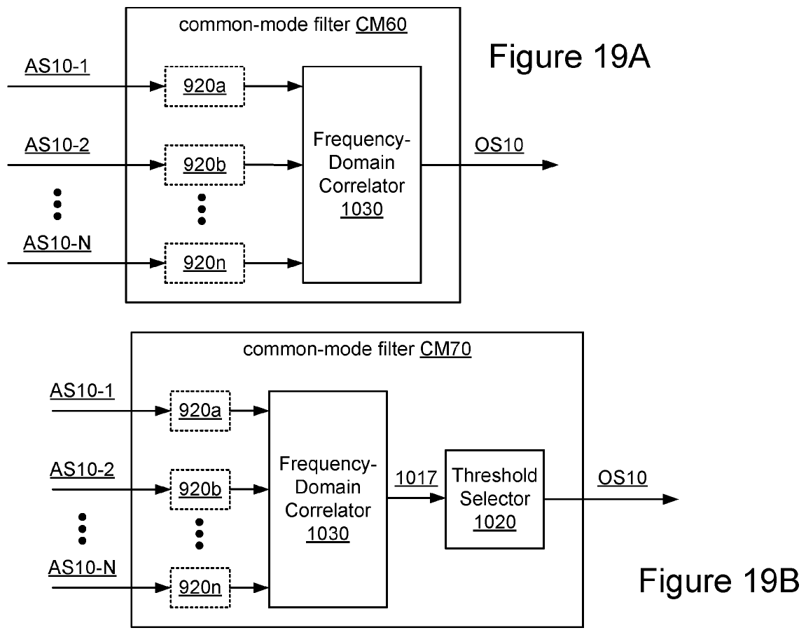

Turning to FIG. 19A, an implementation CM60 of common mode filter subsystem CM10 is illustrated to include a frequency-domain correlator 1030. The frequency-domain correlator 1030 can use any suitable technique to cross-correlate some or all of the frequency-aligned signals AS10-1, AS10-2, . . . , AS10-N in the frequency domain. Because the frequency-aligned signals AS10-1, AS10-2, . . . , AS10-N have substantially the same data-related frequency components and substantially different non-data-related frequency components, the frequency-aligned signals AS10-1, AS10-2, . . . , AS10-N will tend to correlate appreciably more strongly around the data-related frequency components than otherwise. Similar to the time-domain implementation of FIG. 18A, the output of the frequency-domain correlator 730 can be used directly as the digital output signal OS10. Additionally or alternatively, similar to the time-domain implementation of FIG. 18B, the digital output signal OS10 can be generated with added threshold selection. For example, in FIG. 19B, an implementation CM70 of common mode filter subsystem CM10 is illustrated in which the output of the frequency-domain correlator 1030 (already a frequency-domain correlated signal 1017) can be processed by a threshold selector 1020, which can discriminate between those frequency components having magnitudes above a threshold level (i.e., the data-related frequency components) and those frequency components having magnitudes below the threshold level (i.e., the non-data-related frequency components). As described above, some embodiments can apply the discriminating to accept the data-related frequency components, and other embodiments can apply the discriminating rejecting the data-related frequency components.

### EXAMPLES

A method as described herein may be implemented to have an advantage of being able to cancel out spurs generated by the analog section. The analog spurs generated by a converter (e.g., a block downconverter) are also related to the input and LO frequencies. As noted above, for example, a mixer can also be expected to produce spurious responses at frequencies of (p×LO)±(q×AIF) for any integer p and q. To provide a shifted IF to digital converter DC20, the converters of analog converter AC20 (e.g., block downconverters) may be driven by LO signals having different frequencies, which would cause the converters to generate different spurs that may therefore be cancelled out (e.g., by common-mode filtering) along with digital spurs generated by the ADCs of digital converter DC20.

To understand how system S100 may operate to remove spurs that arise from analog converter AC10, we consider an implementation of system S210 in which analog converter AC20 is implemented to include converters CV10-1 and CV10-2, each being a respective instance of a single-conversion block converter. In this example, each converter CV10-1, CV10-2 receives a corresponding instance DS10-1, DS10-2 of the analog data signal that has RF signal content at the frequency 2500 MHz. In the “reference” channel (corresponding to converter CV10-1), the frequency of local oscillator signal LO10-1 is 1500 MHz with a corresponding IF frequency of 1000 MHz. In the second channel (corresponding to converter CV10-2), the frequency of local oscillator signal LO10-2 is 1501 MHz with a corresponding IF frequency of 999 MHz.

A mixer spur calculator may be used to identify mathematical combinations which can be expected to combine to cause problems, and mixer models may be used to determine the power of the spur (e.g., in dBc). In this example, the offending spur generated by converter CV10-1 is at (4×LO)−(2×RF)=(4×1500=6000 MHz)−(2×2500=5000 MHz) which is 6000−5000=1000 MHz, and the calculator puts the power of this spur at −59 dBc. The reference channel would thus have its spur at the IF frequency of 1000 MHz.

On the second channel (corresponding to converter CV10-2), the equation for the offending spur would net (4×1504=6004 MHz)−(2×2500=5000 MHz)=6004−5000=1004 MHz, and the IF would be at 999 MHz. Looking ahead, the frequency alignment performed by subsystem FACM20 in this example will be to generate the FFT of the reference channel and the FFT of the second channel, and to shift the second channel to the exact amount that the second ADC's input is offset compared to the reference channel. The frequency alignment performed by subsystem FACM20 om this example would therefore shift the second channel up by 1 MHz, changing the IF frequency on the second channel to 1000 MHz to match the IF frequency of the reference channel. This alignment would also cause the spur for the second channel to move up to 1005 MHz, so that it would be even further away from the spur on the reference channel that is generated by the same spurious response.

In this example implementation of system S210, digital converter DC20 is implemented to include ADCs ADC1 and ADC2, both being sampled at 2.6 gigasamples per second (Gsps). ADC1 is provided with a 1 GHz-centered spectrum, and ADC2 is provided with a spectrum centered at 999 MHz. For ADC2, the spectrum will be shifted down by 1 MHz, but the spur at (2SC−IF) will be shifted up by 1 MHz. In this case, the spur for ADC1 is at (2.6 GHz×2=5.2 GHz)−1 GHz=4.2 GHz, which we do not care about. However, the spur at (1SC−2IF) is at 2600−(2×1000)=2600−2000=600 MHz, which we do care about. For ADC2, the (1SC−2IF) spur is at 2600−1998=602 MHz. Because we are sampling both ADCs at the same rate, it may be easier to have identical binning characteristics for each channel and may be easier to keep the effective bandwidth the same for each channel.

After performing domain conversion in the frequency alignment on the sampled signals SS10-1, SS10-2 produced by ADC1 and ADC2, respectively, as described above in this example, the FFT data of ADC1 will have signal power in the frequency bin for 1000 MHz and spur power for (1SC−2IF) in the frequency bin for 600 MHz, and the FFT data for ADC2 will have signal power in the frequency bin for 999 MHz and spur power in the frequency bin for 602 MHz. Therefore, when the signal contents are aligned by shifting up the entire bandwidth of sampled signal SS10-2 up by 1 MHz, so that the fundamental signal shifts up 1 MHz from 999 MHz to 1000 MHz to match the fundamental signal in sampled signal SS10-1, the error signal on ADC2 would also shift up 1 MHz from 602 to 603 MHz and would not match the same error signal from ADC1 at 600 MHz. The common-mode acceptance algorithm may be implemented to examine the two aligned signals in similar RBW-bins (Resolution Bandwidth) using a bin-for-bin comparison, and whichever bin has the lower power may be considered the genuine signal and declared the spur-free output for that particular RBW-bin. Bins with identical powers may be considered genuine signals and may be passed to the spur-free output. In this example, we pass the signal at 1000 MHz and we reject both the error signal at 600 MHz (from ADC1) in sampled signal SS10-1 and the error signal at 603 MHz (from ADC2) in sampled signal SS10-2.

Vector data with phase and amplitude can be similarly compared. It may be desired to preserve phase data so that it can be used to further distinguish a real signal from an internally generated spur. After calibration, true signals should be in phase. Using phase in the algorithm could have a benefit of canceling noise especially from other Nyquist zones which are not being tuned in by the algorithm.

Single ADC

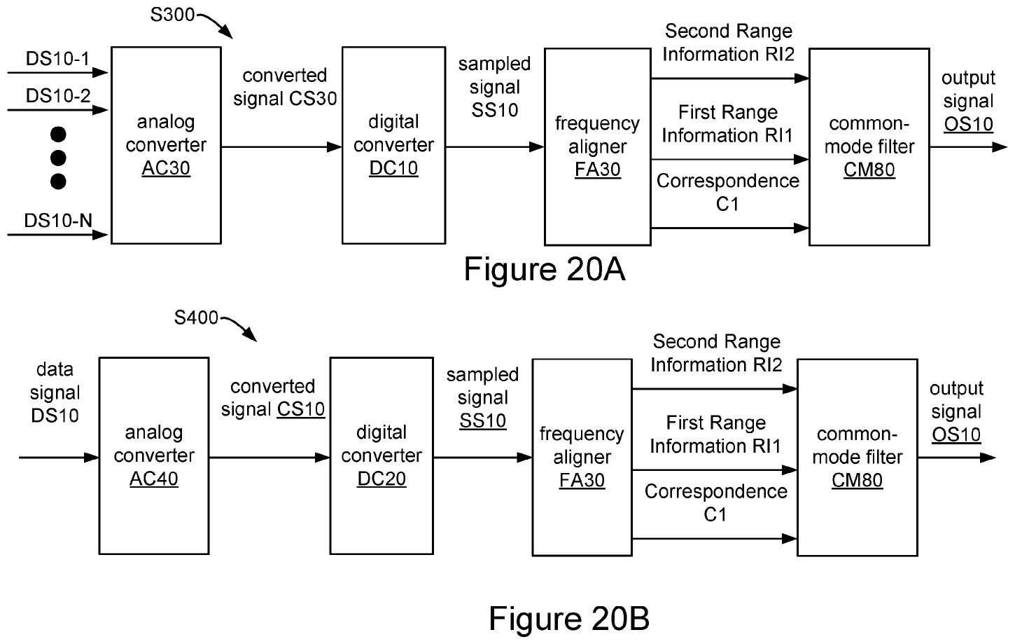

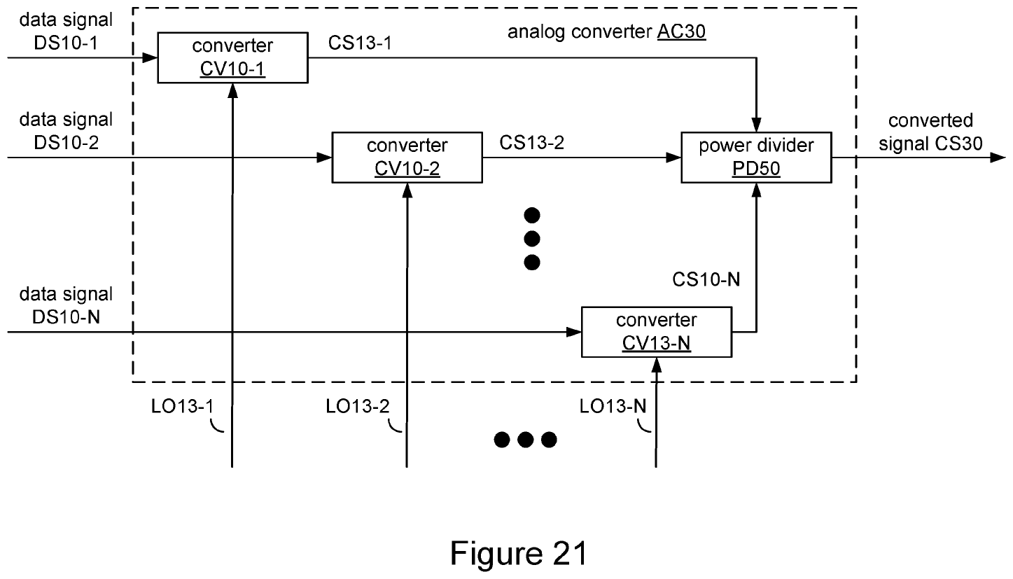

Several interesting embodiments may be realized using an implementation of digital converter DC10 that includes a single ADC. For example, different bands of the same ADC may be utilized by including multiple frequency-translated versions of the signal content in the same converted signal. FIG. 20A shows a block diagram of a system 5300 according to another general configuration. System 5300 includes an implementation AC30 of analog converter AC10 that receives instances DS10-1. DS10-2, . . . , DS10-N of data signal DS10 and produces a converted signal CS30 that includes multiple frequency-translated versions of the signal content of data signal DS10. FIG. 21 shows a block diagram of analog converter AC30, which includes multiple instances CV10-1, CV10-2, . . . , CV10-N of converter CV10 as described above and a power divider PD50 (e.g., a power splitter), which may be active or passive and may be implemented according to any appropriate analog signal duplicating technique.

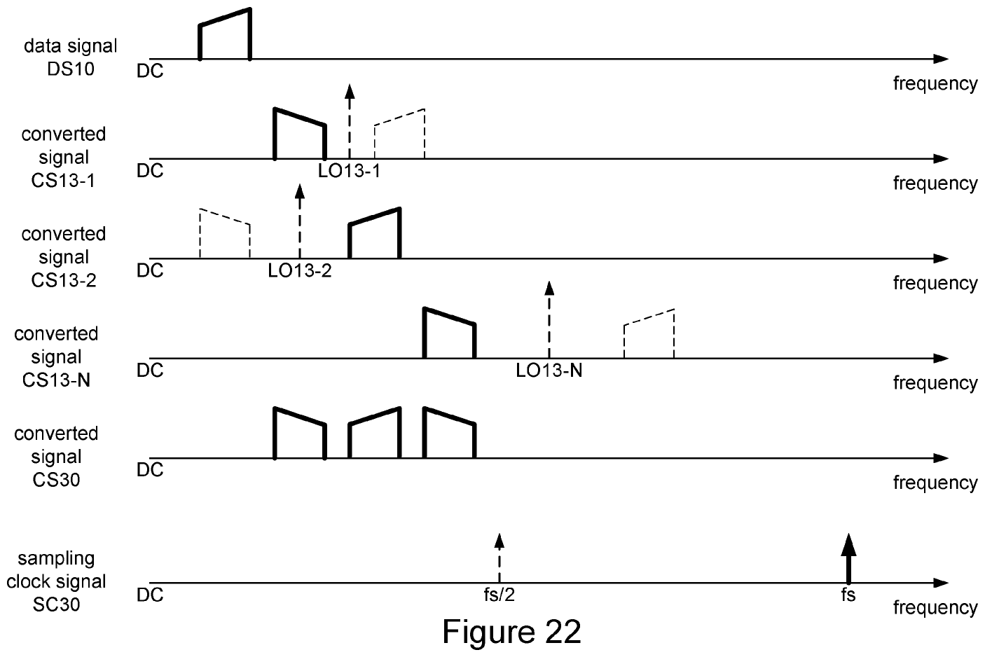

Power divider PD50 combines the converted signals CS13-1, CS13-2, . . . , CS13-N produced by CV10-1, CV10-2, . . . , CV10-N to produce a converted signal CS30 that includes multiple frequency-translated versions of the signal content of data signal DS10 (in this example, each shifted by a corresponding one of local oscillator signals LO13-1, LO13-2, . . . , LO13-N). FIG. 22 shows an example of the frequency-domain locations of the frequency-translated versions of the signal content in the signals DS10, CS13-1 to CS13-N, and CS30. As shown in FIG. 22, digital converter DC10 samples converted signal CS30 according to sampling clock signal SC30 to produce sampled signal SS10, where the sampling rate (e.g., the frequency of sampling clock signal SC30) is more than twice as great as the highest frequency among the multiple frequency-translated versions of the signal content of data signal DS10.

System S300 may also include an implementation FA30 of frequency aligner SA10 that is configured to indicate a correspondence C1 in sampled signal SS10 among the ranges of the multiple frequency-translated versions of the signal content. For example, frequency aligner FA30 may be configured to indicate, for each bin of the frequency range R11 of the first frequency-translated version, a corresponding bin of the second frequency range R12 of the second frequency-translated version (e.g., accounting for the offset between the signal content in the two ranges as produced by analog converter AC30), and so on for the rest of the N frequency-translated versions. System S300 may also include an implementation CM80 of common-mode filter CM10 that is configured to perform a common-mode filtering operation, based on information from the first frequency range of the sampled signal, information from the second frequency range of the sampled signal, and the indicated correspondence, to produce digital output signal OS10.

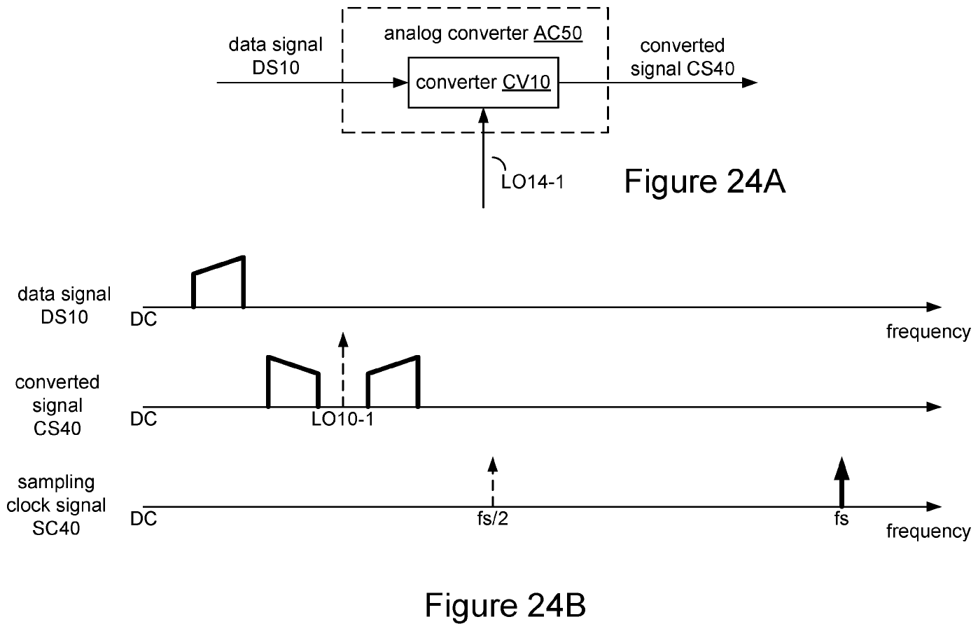

FIG. 24B shows an example of a double sideband signal presented to one ADC. In this configuration, the analog input signal is split by a mixer. The mixer creates two images of the input signal that are equally spaced around the LO frequency. It may be desired to pass the mixer output through a notch filter to strip off the LO component. What is left is two images having the same signal content, with one of the images being reversed, and different noise profiles. The processing may involve performing an FFT on the sampled signal (e.g., by frequency aligner FA30), which may include a corresponding frequency range for the lower sideband and a corresponding frequency range for the upper sideband. These two ranges may be parsed out in frequency so that there are two sets of data (i.e., one for each sideband), except that one sideband will be reversed as far as the frequency sense. Common-mode filter CM80 may perform a common-mode acceptance algorithm to compare the frequencies which correspond to each other, effectively reversing back the reversed spectrum and outputting a cleaned-up spectrum.

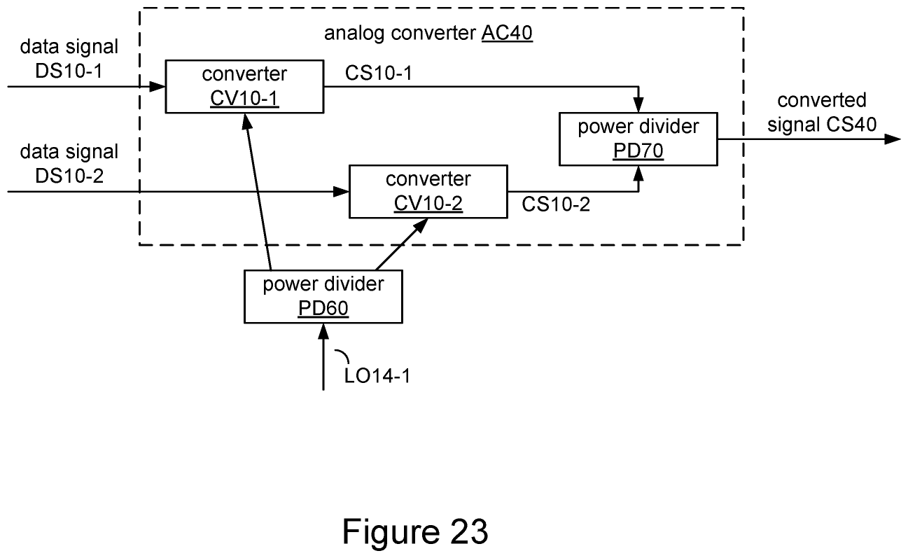

FIG. 20B shows a block diagram of a system 5400 according to another general configuration. System 5400 includes an implementation AC40 of analog converter AC10 (e.g., as an instance of converter CV10 or CV20) that receives system input signal DS10 having signal content and produces a converted signal CS10. FIG. 23 shows a block diagram of analog converter AC40, in which converter CV10-1 converts an instance DS10-1 of data signal DS10 according to local oscillator signal LO14-1 to frequency-translate the signal content to one of the upper sideband or the lower sideband, and converter CV10-2 converts an instance DS10-2 of data signal DS10 according to local oscillator signal LO14-1 to frequency-translate the signal content to the other of the upper sideband or the lower sideband. FIG. 24A shows a block diagram of analog converter AC50 that produces a similar result (converted signal CS40) using one converter CV10, and FIG. 24B shows an example of the double sideband signal of converted signal CS40 as presented to one ADC. In these examples, digital converter DC20 samples converted signal CS40, which in this case includes a first frequency range that includes the signal content and a second frequency range that is separate from the first frequency range and also includes the signal content, to produce sampled signal SS10.

System S400 may also include an instance of frequency aligner SA10 configured to indicate a correspondence C1 in sampled signal SS10 between the first frequency range and the second frequency range, and an instance of common-mode filter CM80 that is configured to perform a common-mode filtering operation, based on information from the first frequency range of the sampled signal, information from the second frequency range of the sampled signal, and the indicated correspondence, to produce a digital output signal. Alternatively, systems S300 and S400 may be implemented to include an instance of common-mode filter CM10 as described herein instead of common-mode filter CM80, and in such cases frequency aligner FA30 may be implemented to perform the alignment of the multiple frequency-translated versions of the signal content (which may include reversing a frequency sense of one or more of the versions) in order to present a set of frequency aligned signals to common-mode filter CM10 (e.g., as described herein with reference to aligned signals AS10-1, AS10-2, . . . , AS10-3).

Time Division Multiplexing

In a further example, system S100 may be implemented to frequency-align and perform common-mode filtering on signal content that is frequency-translated according to different shift frequencies at different times. In such a case, analog converter AC10 may be implemented to include an instance of converter CV10 that is driven by a first local oscillator frequency LO10-1 over a first collection interval and is driven by a different second local oscillator frequency LO10-2 over a second collection interval (which may have the same length as the first collection interval). The resulting converted signal CS10 may be sampled by digital converter DC10 to produce a sampled signal SS10, and the portions of sampled signal SS10 that correspond to the two collection intervals may be frequency-aligned (e.g., based on a difference between the local oscillator signals LO10-1 and LO10-2) and processed by common-mode filtering to produce an output signal OS10. Such an implementation of system S100 may be useful for an application in which the data signal DS10 is expected to be uniform or consistent over time.

In general, analog converter AC10 may be implemented to frequency-translate the signal content of data signal DS10 by a different corresponding shift frequency during each of two or more collection intervals (e.g., to frequency-translate the signal content of data signal DS10 by a first corresponding shift frequency during a first collection interval, to frequency-translate the signal content of data signal DS10 by a second corresponding shift frequency during a second collection interval, and so on), where the collection intervals may have the same length or may have different lengths, and where analog converter AC10 (e.g., converter CV10) may be implemented to perform the frequency translation in a single stage (e.g., by one mixer) or in multiple stages (e.g., by multiple mixers). The portions of sampled signal SS10 that correspond to the various collection intervals may be frequency-aligned (e.g., based on differences among the corresponding shift frequencies, as described herein) and processed by common-mode filtering (e.g., by selecting the minimum-magnitude value at each frequency bin) to produce an output signal OS10.

A potential advantage of such an approach is that digital converter DC10 may be implemented to include only one ADC, which may represent a significant cost savings. As noted above, such an implementation of system S100 may be useful for an application in which the data signal DS10 is expected to be uniform or consistent over time, such as a signal from a sensor responding to a stimulus that is mostly fixed. Examples of such a sensor may include a camera pixel in a fixed-field region of an image, or an oxygen sensor in an internal combustion engine. By reducing noise that may be introduced by digital converter DC10 (e.g., by ADC1), such an implementation of system S100 may support the use of a less expensive ADC (e.g., an ADC having fewer bits of resolution) in such applications.

Changing Clock

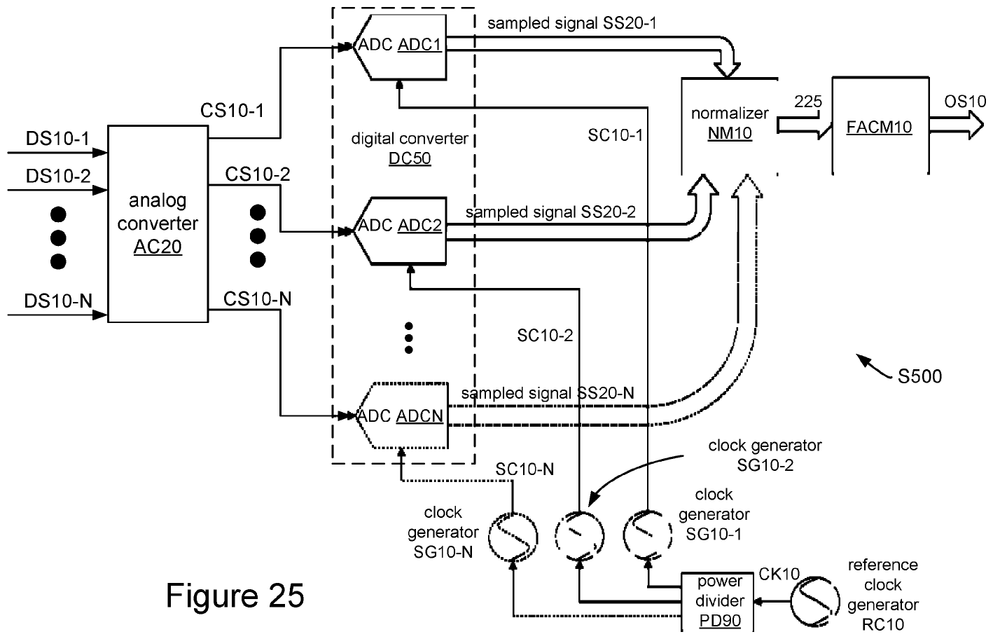

FIG. 25 shows an example of a system S500 for presenting the same signal content at different AIFs for digitization as described herein (e.g., using an instance of analog converter AC20), and digitizing the resulting converted signals at different sampling rates (e.g., as described in WO 2020/150670 A1). In this case, the bandwidths of the resulting sampled signals SS20-1, SS20-2, . . . , SS20-N may differ from one another, so that it may be desired to normalize the sampled signals to a common bandwidth (e.g., as described in WO 2020/150670 A1, such as by resampling in the time domain or frequency domain) before performing the common-mode acceptance algorithm. For example, the common acceptance algorithm in this process may have the additional step of normalizing the input data in the frequency domain. In this example, system S500 may include an FPGA having a normalizer NM10 that is configured to receive the sampled signals SS10 and to produce a corresponding set of common- bandwidth signals 225 (e.g., as described in WO 2020/150670 A1), and an implementation of frequency aligner and common-mode filter subsystem FACM10 that is configured to receive the set of common-bandwidth signals and to produce output signal OS10. WO 2020/150670 A1 is hereby incorporated by reference for its description of using ADCs at different sampling rates (including the selection of those rates) and normalizing sampled signals to produce a set of common-bandwidth signals (e.g., in which each value of an ordered sequence of values of a first of the set of common-bandwidth signals represents a same interval of a domain of the analog input signal as a corresponding value of an ordered sequence of values of a second of the set of common-bandwidth signals).

Closing

The various techniques can be implemented with any suitable hardware and/or software component(s) and/or module(s), including, but not limited to circuits, application-specific integrated circuits (ASICs), optical processing techniques, general-purpose processors, digital signal processors (DSPs), field-programmable gate arrays (FPGAs), programmable logic devices (PLD), discrete gates, transistor logic devices (e.g., emitter-coupled logic (ECL)), discrete hardware components, or combinations thereof. For example, steps of methods or algorithms (e.g., frequency alignment and/or common-mode filtering as described herein), or other functionality described in connection with embodiments, can be embodied directly in hardware, in a software module executed by a processor, or in a combination of the two. A software module may reside in any form of tangible storage medium. Some examples of storage media that may be used include random-access memory (RAM), read-only memory (ROM), flash memory, EPROM memory, EEPROM memory, registers, a hard disk, a removable disk, a CD-ROM and so forth. A storage medium may be coupled to a processor such that the processor can read information from, and write information to, the storage medium. In the alternative, the storage medium may be integral to the processor. A software module may be a single instruction, or many instructions, and may be distributed over several different code segments, among different programs, and across multiple storage media. Thus, a computer program product may perform operations presented herein. For example, such a computer program product may be a computer-readable tangible medium having instructions stored (and/or encoded) thereon, the instructions being executable by one or more processors to perform the operations described herein (e.g., a method for spurious information reduction in a data signal as disclosed herein, operations of frequency alignment and/or common-mode filtering as described herein). The computer program product may include packaging material. Software or instructions may also be transmitted over a transmission medium. For example, software may be transmitted from a website, server, or other remote source using a transmission medium such as a coaxial cable, fiber optic cable, twisted pair, digital subscriber line (DSL), or wireless technology such as infrared, radio, or microwave.

The methods disclosed herein include one or more actions for achieving the described method. The method and/or actions can be interchanged with one another without departing from the scope of the claims. In other words, unless a specific order of actions is specified, the order and/or use of specific actions can be modified without departing from the scope of the claims. The various operations of methods and functions of certain system components described above can be performed by any suitable means capable of performing the corresponding functions.

Other examples and implementations are within the scope and spirit of the disclosure and appended claims. For example, features implementing functions can also be physically located at various positions, including being distributed such that portions of functions are implemented at different physical locations. Also, as used herein, including in the claims, “or” as used in a list of items prefaced by “at least one of” indicates a disjunctive list such that, for example, a list of “at least one of A, B, or C” means A or B or C or AB (i.e., A and B) or AC or BC or ABC (i.e., A and B and C). Further, the term “exemplary” does not mean that the described example is preferred or better than other examples.

Unless expressly limited by its context, the term “signal” is used herein to indicate any of its ordinary meanings, including a state of a memory location (or set of memory locations) as expressed on a wire, bus, or other transmission medium. Unless expressly limited by its context, the term “generating” is used herein to indicate any of its ordinary meanings, such as computing or otherwise producing. Unless expressly limited by its context, the term “calculating” is used herein to indicate any of its ordinary meanings, such as computing, evaluating, estimating, and/or selecting from a plurality of values. Unless expressly limited by its context, the term “obtaining” is used to indicate any of its ordinary meanings, such as calculating, deriving, receiving (e.g., from another element or device), and/or retrieving (e.g., from an array of storage elements). Unless expressly limited by its context, the term “selecting” is used to indicate any of its ordinary meanings, such as identifying, indicating, applying, and/or using at least one, and fewer than all, of a set of two or more. Unless expressly limited by its context, the term “determining” is used to indicate any of its ordinary meanings, such as deciding, establishing, concluding, calculating, selecting, and/or evaluating. Where the term “comprising” is used in the present description and claims, it does not exclude other elements or operations. The term “based on” (as in “A is based on B”) is used to indicate any of its ordinary meanings, including the cases (i) “derived from” (e.g., “B is a precursor of A”), (ii) “based on at least” (e.g., “A is based on at least B”) and, if appropriate in the particular context, (iii) “the same as” or “equal to” (e.g., “A is the same as B,” “A is equal to B”). Similarly, the term “in response to” is used to indicate any of its ordinary meanings, including “in response to at least.” Unless otherwise indicated, the terms “at least one of A, B, and C,” “one or more of A, B, and C,” “at least one among A, B, and C,” and “one or more among A, B, and C” indicate “A and/or B and/or C.” Unless otherwise indicated, the terms “each of A, B, and C” and “each among A, B, and C” indicate “A and B and C.” The term “information from each of A, B, and C” means an aggregation of information from A, (possibly different) information from B, and (possibly different) information from C.

Unless indicated otherwise, any disclosure of an operation of an apparatus having a particular feature is also expressly intended to disclose a method having an analogous feature (and vice versa), and any disclosure of an operation of an apparatus according to a particular configuration is also expressly intended to disclose a method according to an analogous configuration (and vice versa). The term “configuration” may be used in reference to a method, apparatus, and/or system as indicated by its particular context. The terms “method,” “process,” “procedure,” and “technique” are used generically and interchangeably unless otherwise indicated by the particular context. A “task” having multiple subtasks is also a method. The terms “apparatus” and “device” are also used generically and interchangeably unless otherwise indicated by the particular context. The terms “element” and “module” are typically used to indicate a portion of a greater configuration. Unless expressly limited by its context, the term “system” is used herein to indicate any of its ordinary meanings, including “a group of elements that interact to serve a common purpose.”

Unless initially introduced by a definite article, an ordinal term (e.g., “first,” “second,” “third,” etc.) used to modify a claim element does not by itself indicate any priority or order of the claim element with respect to another, but rather merely distinguishes the claim element from another claim element having a same name (but for use of the ordinal term). Unless expressly limited by its context, each of the terms “plurality” and “set” is used herein to indicate an integer quantity that is greater than one.

Various changes, substitutions, and alterations to the techniques described herein can be made without departing from the technology of the teachings as defined by the appended claims. Moreover, the scope of the disclosure and claims is not limited to the particular aspects of the process, machine, manufacture, composition of matter, means, methods, and actions described above. Processes, machines, manufacture, compositions of matter, means, methods, or actions, presently existing or later to be developed, that perform substantially the same function or achieve substantially the same result as the corresponding aspects described herein can be utilized. Accordingly, the appended claims include within their scope such processes, machines, manufacture, compositions of matter, means, methods, or actions.

1-20. (canceled)

21. A method of spurious information reduction in a data signal, the method comprising:
receiving at least one instance of an analog data signal that has a signal content in an original frequency band;
producing a plurality of analog converted signals, including, for each of the plurality of analog converted signals, frequency translating the signal content of the analog data signal from the original frequency band by a corresponding shift frequency to produce the analog converted signal to have the frequency-translated signal content, the corresponding shift frequency being different than the corresponding shift frequency for each other analog converted signal of the plurality of analog converted signals;
based on the plurality of converted signals, generating a corresponding plurality of digital sampled signals, including, for each of the plurality of digital sampled signals, sampling the frequency-translated signal content of at least a corresponding one of the plurality of analog converted signals to produce the digital sampled signal to have a sampled version of the frequency-translated signal content;
aligning information from the sampled versions among the plurality of digital sampled signals, based on the corresponding shift frequencies; and
performing a common-mode filtering operation, based on the aligned information, to produce a digital output signal.

22. (canceled)

23. The method according to claim 21, wherein the at least one instance of the analog data signal comprises a plurality of instances of the analog data signal, and
wherein the receiving includes receiving each of the plurality of instances of the analog data signal from a corresponding one of a plurality of elements of an antenna array.

24. The method according to claim 21, wherein, for each pair among the plurality of analog converted signals, a difference between the corresponding shift frequencies of the pair is not an integer multiple of a difference between the corresponding shift frequencies of any other pair among the plurality of analog converted signals.

25. The method according to claim 21, wherein, for each pair among the plurality of analog converted signals, a difference between the corresponding shift frequencies of the pair is coprime to a difference between the corresponding shift frequencies of each other pair among the plurality of analog converted signals.

26. The method according to claim 21, wherein generating the corresponding plurality of sampled signals comprises:
sampling a first analog converted signal among the plurality of analog converted signals at a first sampling rate to generate a first digital sampled signal among the plurality of digital sampled signals; and
sampling a second analog converted signal among the plurality of analog converted signals at the first sampling rate to generate a second digital sampled signal among the plurality of digital sampled signals.

27. The method according to claim 21, wherein generating the corresponding plurality of sampled signals comprises:
sampling a first analog converted signal among the plurality of analog converted signals at a first sampling rate to generate a first digital sampled signal among the plurality of digital sampled signals; and
sampling a second analog converted signal among the plurality of analog converted signals at a second sampling rate to generate a second digital sampled signal among the plurality of digital sampled signals,
wherein the first sampling rate is different than the second sampling rate.

28. The method according to claim 21, wherein aligning the information from the sampled versions includes aligning the information in a frequency domain.

29. The method according to claim 21, wherein the method includes converting each of the plurality of sampled signals to a plurality of bins in a frequency domain, and
wherein the aligning includes aligning the information from the sampled versions in the frequency domain, and
wherein performing the common-mode filtering operation includes computing a corresponding one of a plurality of output components based on a maximum magnitude for the bin as selected across the aligned information from the sampled versions.

30. The method according to claim 21, wherein the method includes converting each of the plurality of sampled signals to a plurality of bins in a frequency domain, and
wherein the aligning includes aligning the information from the sampled versions in the frequency domain, and
wherein performing the common-mode filtering operation includes computing a corresponding one of a plurality of output components based on an average magnitude for the bin as selected across the aligned information from the sampled versions.

31. The method according to claim 21, wherein performing the common-mode filtering operation includes executing a common-mode acceptance algorithm on the aligned information.

32. The method according to claim 21, wherein performing the common-mode filtering operation includes executing a voting algorithm on the aligned information.

33. The method according to claim 21, wherein performing the common-mode filtering operation includes performing a spectral analysis to determine frequency content in each of a plurality of frequency-aligned signals.

34. The method according to claim 21, wherein the aligning the information from the sampled versions of the frequency-translated signal contents among the plurality of digital sampled signals and performing the common-mode filtering operation are performed within one or more arrays of logic elements.

35. The method according to claim 21, wherein, for each of the plurality of analog converted signals, the corresponding shift frequency is based on at least one local oscillator frequency.

36. The method according to claim 35, wherein the at least one local oscillator frequency for a first analog converted signal among the plurality of analog converted signals is derived from the same reference clock signal as the at least one local oscillator frequency for a second analog converted signal among the plurality of analog converted signals.

37. The method according to claim 21, wherein, for at least one of the plurality of analog converted signals, the corresponding shift frequency is based on at least two different local oscillator frequencies.

38. The method according to claim 21, wherein the aligning information from the sampled versions is based on at least one difference between at least one pair of the corresponding shift frequencies.

39. (canceled)

40. The method according to claim 21, wherein the method includes converting each of the plurality of sampled signals to a plurality of bins in a frequency domain, and
wherein the aligning includes aligning the information from the sampled versions in the frequency domain, and
wherein performing the common-mode filtering operation includes computing a corresponding one of a plurality of output components based on a minimum magnitude for the bin as selected across the aligned information from the sampled versions.

41. (canceled)

42. A system for spurious information reduction in a data signal, the system comprising:
an analog converter configured to receive a plurality of analog input signals, each of the plurality of analog input signals being based on a corresponding one of a plurality of instances of a system input signal, and to generate a plurality of converted signals,
wherein the analog converter is configured to generate a first of the plurality of converted signals by mixing a first of the plurality of analog input signals with a first local oscillator signal that has a first local oscillator frequency, and
wherein the analog converter is configured to generate a second of the plurality of converted signals by mixing a second of the plurality of analog input signals with a second local oscillator signal that has a second local oscillator frequency which is different than the first local oscillator frequency;
a digital converter configured to receive a combined signal that is based on the plurality of converted signals and to generate a corresponding sampled signal, wherein the combined signal includes a first frequency range that includes signal content from the first of the plurality of converted signals and a second frequency range that includes signal content from the second of the plurality of converted signals;
a signal aligner configured to indicate a correspondence in the sampled signal between the first frequency range and the second frequency range; and
a common-mode filter configured to perform a common-mode filtering operation, based on information from the first frequency range of the sampled signal, information from the second frequency range of the sampled signal, and the indicated correspondence, to produce a digital output signal.

43. A system for spurious information reduction in a data signal, the system comprising:
an analog converter configured to receive an analog input signal having signal content and to generate a converted signal;
a digital converter configured to receive the converted signal and to generate a corresponding sampled signal, wherein the converted signal includes a first frequency range that includes the signal content and a second frequency range that is separate from the first frequency range and also includes the signal content;
a signal aligner configured to indicate a correspondence in the sampled signal between the first frequency range and the second frequency range; and
a common-mode filter configured to perform a common-mode filtering operation, based on information from the first frequency range of the sampled signal, information from the second frequency range of the sampled signal, and the indicated correspondence, to produce a digital output signal.
